(19) United States
(12) Patent Application Publication
(10) Pub. No.: US 2021/0255370 A1
(43) Pub. Date: Aug. 19, 2021

(54) LIQUID LENSES AND METHODS OF MANUFACTURING LIQUID LENSES

(71) Applicant: CORNING INCORPORATED, CORNING, NY (US)

(72) Inventors: Michael Anzlowar, Santa Barbara, CA (US); Robert Alan Bellman, Ithaca, NY (US); Shiwen Liu, Painted Post, NY (US); Ines Wyrsta, Santa Barbara, CA (US)

(21) Appl. No.: 17/054,929

(22) PCT Filed: May 15, 2019
(86) PCT No.: PCT/US2019/032397

§ 371 Date: Nov. 12, 2020

Related U.S. Application Data
(60) Provisional application No. 62/674,528, filed on May 21, 2018.

(51) Int. Cl. G02B 3/14; G02B 26/00; G02B 3/00; G03F 7/00

(52) U.S. Cl. CPC G02B 3/14; G03F 7/0005; G02B 3/0012; G02B 26/005

(57) ABSTRACT

A method of fabricating a liquid lens or an array of liquid lenses, and the corresponding liquid lens or array of lenses is disclosed. The method includes patterning an insulative layer (132) by photolithographic techniques to expose a portion of the conductive layer (124) and a portion of the insulative layer (132) having a surface energy below 40 mJ/m². In further embodiments, the liquid lens includes an interface (110) forming a lens between a polar liquid (106) and a non-polar liquid (108) disposed within a cavity (104). The interface intersects a surface of the insulative layer (132) having a surface energy below 40 mJ/m².

### CROSS-REFERENCE TO RELATED APPLICATIONS

This application claims the benefit of priority under 35 U.S.C. § 119 of U.S. Provisional Application No. 62/674,528, filed May 21, 2018, the content of which is incorporated herein by reference in its entirety.

### FIELD

The present disclosure relates generally to a liquid lens as well as methods for manufacturing and operating a liquid lens and, more particularly, to liquid lenses including a conductive layer and an insulative layer as well as methods for manufacturing and operating liquid lenses including a conductive layer and an insulative layer.

### BACKGROUND

Liquid lenses generally include two immiscible liquids disposed within a cavity of a lens body. Varying the electric field to which the liquids are subjected can vary the wettability of one of the liquids with respect to a surface within the cavity and can, thereby, vary a shape of an interface (e.g., liquid lens) formed between the two liquids. The liquid lens can function and, therefore, be employed as an optical lens in a variety of applications.

### SUMMARY

The following presents a simplified summary of the disclosure to provide a basic understanding of some embodiments described in the detailed description.

In some embodiments, a method of manufacturing a liquid lens can include applying a mask layer to an insulative layer. A conductive layer may be disposed between a substrate and the insulative layer within a bore of the substrate. The method can further include selectively exposing a first portion of the mask layer to electromagnetic radiation without exposing a second portion of the mask layer to the electromagnetic radiation. The method can further include developing the first portion of the mask layer to expose a first portion of the insulative layer. The method can further include selectively etching the first portion of the insulative layer to expose a portion of the conductive layer comprising a first pattern corresponding to the first portion of the mask layer. The method can further include removing the second portion of the mask layer to expose a second portion of the insulative layer comprising a second pattern corresponding to the second portion of the mask layer and a surface energy below 40 mJ/m².

In some embodiments, the second portion of the insulative layer can comprise a hydrophobic surface.

In some embodiments, the mask layer can comprise a photoresist.

In some embodiments, the insulative layer can comprise Parylene.

In some embodiments, the applying the mask layer can comprise spraying a photoresist material onto the insulative layer.

In some embodiments, the etching the first portion of the insulative layer to expose a portion of the conductive layer can comprise plasma etching.

In some embodiments, the method can comprise adding a polar liquid and a non-polar liquid to a cavity that can be defined at least in part by a bore of the substrate. The polar liquid and the non-polar liquid can be substantially immiscible such that an interface defined between the polar liquid and the non-polar liquid forms a lens.

In some embodiments, the method can comprise bonding a second substrate to the substrate to hermetically seal the polar liquid, the non-polar liquid, and the second portion of the insulative layer within the cavity.

In some embodiments, the method can comprise subjecting the polar liquid and the non-polar liquid to an electric field and changing a shape of the interface by adjusting the electric field to which the polar liquid and the non-polar liquid are subjected.

In some embodiments, a liquid lens manufactured by the method can comprise the substrate, the conductive layer, and the second portion of the insulative layer.

In some embodiments, a method of manufacturing can provide an array comprising a plurality of liquid lenses. The method can include applying a mask layer to an insulative layer. A conductive layer can be disposed between a substrate and the insulative layer within a plurality of bores of the substrate. The method can further include selectively exposing a plurality of first portions of the mask layer to electromagnetic radiation without exposing a plurality of second portions of the mask layer to the electromagnetic radiation. The method can further include developing the plurality of first portions of the mask layer to expose a plurality of first portions of the insulative layer. The method can further include selectively etching the plurality of first portions of the insulative layer to expose a plurality of portions of the conductive layer comprising a first pattern corresponding to the plurality of first portions of the mask layer. The method can further include removing the plurality of second portions of the mask layer to expose a plurality of second portions of the insulative layer comprising a second pattern corresponding to the plurality of second portions of the mask layer and a surface energy below 40 mJ/m².

In some embodiments, the plurality of second portions of the insulative layer can comprise a hydrophobic surface.

In some embodiments, the mask layer can comprise a photoresist.

In some embodiments, the insulative layer can comprise Parylene.

In some embodiments, the applying the mask layer can comprise spraying a photoresist material onto the insulative layer.

In some embodiments, the selective etching the plurality of first portions of the insulative layer to expose a plurality of portions of the conductive layer can comprise plasma etching.

In some embodiments, the method can include adding a polar liquid and a non-polar liquid to each cavity of the plurality of cavities. Each cavity of the plurality of cavities can be defined at least in part by a corresponding bore of a plurality of bores of the substrate. The polar liquid and the non-polar liquid can be substantially immiscible such that an interface defined between the polar liquid and the non-polar liquid in each cavity of the plurality of cavities can define a corresponding lens of a plurality of lenses.

In some embodiments, the method can comprise bonding a second substrate to the first substrate to hermetically seal the polar liquid and the non-polar liquid of each corresponding cavity of the plurality of cavities and a corresponding second portion of the plurality of second portions of the insulative layer within the corresponding cavity of the plurality of cavities.

In some embodiments, the method can comprise separating each liquid lens of the plurality of liquid lenses from the array.

In some embodiments, the method can comprise subjecting the polar liquid and the non-polar liquid of at least one liquid lens of the plurality of liquid lenses to an electric field and changing a shape of the corresponding interface by adjusting the electric field to which the polar liquid and the non-polar liquid are subjected.

In some embodiments, a liquid lens comprises a cavity defined at least in part by a bore of a substrate. The liquid lens can include a conductive layer disposed within the bore and an insulative layer disposed within the bore such that the conductive layer is disposed between the substrate and the insulative layer. The liquid lens can further include a polar liquid and a non-polar liquid disposed within the cavity. The polar liquid and the non-polar liquid can be substantially immiscible such that an interface defined between the polar liquid and the non-polar liquid forms a lens. The interface can intersect a surface of the insulative layer including a surface energy below 40 mJ/m².

In some embodiments, the surface of the insulative layer can comprise a hydrophobic surface.

In some embodiments, the insulative layer can comprise Parylene.

In some embodiments, the liquid lens can further comprise a second substrate bonded to the substrate, wherein the polar liquid, the non-polar liquid, and the insulative layer are hermetically sealed within the cavity.

In some embodiments, an array can comprise a plurality of liquid lenses. The array can comprise a substrate comprising a plurality of bores. The array can further comprise a plurality of cavities. Each cavity of the plurality of cavities can be defined at least partially by a corresponding bore of the plurality of bores. The array can further comprise a conductive layer disposed within each bore of the plurality of bores. The array can still further comprise an insulative layer disposed within each bore of the plurality of bores. The conductive layer can be disposed between the substrate and the insulative layer within each bore of the plurality of bores. The array can include a polar liquid and a non-polar liquid disposed within each cavity of the plurality of cavities. The polar liquid and the non-polar liquid can be substantially immiscible such that an interface defined between the polar liquid and the non-polar liquid in each cavity of the plurality of cavities defines a corresponding lens of the plurality of liquid lenses. The interface of each cavity of the plurality of cavities can intersect a corresponding surface portion of the insulative layer located within each corresponding bore of the plurality of bores. Each surface portion of the insulative layer can include a surface energy below 40 mJ/m².

In some embodiments, each surface portion of the insulative layer can comprise a hydrophobic surface.

In some embodiments, the insulative layer can comprise Parylene.

In some embodiments, the array can further comprise a second substrate bonded to the substrate. The polar liquid and the non-polar liquid of each corresponding cavity of the plurality of cavities and each surface portion of the insulative layer of each corresponding bore of the plurality of bores can be hermetically sealed within the corresponding cavity of the plurality of cavities.

### BRIEF DESCRIPTION OF THE DRAWINGS

These and other features, embodiments and advantages are better understood when the following detailed description is read with reference to the accompanying drawings, in which:

FIG. 1 schematically illustrates a cross-sectional view of an exemplary embodiment a liquid lens in accordance with embodiments of the disclosure;

FIG. 2 shows a top (plan) view of the liquid lens along line 2-2 of FIG. 1 in accordance with embodiments of the disclosure;

FIG. 3 shows a bottom view of the liquid lens along line 3-3 of FIG. 1 in accordance with embodiments of the disclosure;

FIG. 4 shows an enlarged view of a portion of the liquid lens taken at view 4 of FIG. 1, including a conductive layer and an insulative layer in accordance with embodiments of the disclosure;

FIG. 5 shows an exemplary method of manufacturing the liquid lens of FIG. 4 including applying a conductive layer and an absorber layer in accordance with embodiments of the disclosure;

FIG. 6 shows an exemplary method of manufacturing the liquid lens of FIG. 4 including applying an insulative layer to the absorber layer and the conductive layer of FIG. 5 in accordance with embodiments of the disclosure;

FIG. 7 shows an exemplary method of manufacturing the liquid lens of FIG. 4 including a method of patterning the insulative layer of FIG. 6 including applying a mask layer in accordance with embodiments of the disclosure;

FIG. 8 shows an exemplary method of manufacturing the liquid lens of FIG. 4 including the method of patterning the insulative layer including positioning a pattern and exposing at least a portion of the mask layer of FIG. 7 to electromagnetic radiation in accordance with embodiments of the disclosure;

FIG. 9 shows an exemplary method of manufacturing the liquid lens of FIG. 4 including the method of patterning the insulative layer including developing the at least an exposed portion of the mask layer of FIG. 8 and providing an undeveloped portion of the mask layer in accordance with embodiments of the disclosure;

FIG. 10 shows an exemplary method of manufacturing the liquid lens of FIG. 4 including the method of patterning the insulative layer including etching the insulative layer based on the undeveloped portion of the mask layer of FIG. 9 in accordance with embodiments of the disclosure;

FIG. 11 shows an exemplary method of manufacturing the liquid lens of FIG. 4 including the method of patterning the insulative layer including removing the undeveloped portion of the mask layer after the method of etching the insulative layer based on the undeveloped portion of the mask layer of FIG. 10 in accordance with embodiments of the disclosure.

FIG. 12 shows an exemplary embodiment of the patterned insulative layer manufactured by the exemplary methods of FIGS. 6-11 after the method of removing the undeveloped portion of the mask layer of FIG. 11 in accordance with embodiments of the disclosure; and

FIG. 13 shows an exemplary embodiment of a portion of the liquid lens including the patterned insulative layer of FIG. 12 in accordance with embodiments of the disclosure.

### DETAILED DESCRIPTION

Embodiments will now be described more fully hereinafter with reference to the accompanying drawings in which exemplary embodiments are shown. Whenever possible, the same reference numerals are used throughout the drawings to refer to the same or like parts. However, this disclosure may be embodied in many different forms and should not be construed as limited to the embodiments set forth herein.

It is to be understood that specific embodiments disclosed herein are intended to be exemplary and therefore non-limiting. For purposes of the disclosure, in some embodiments, a liquid lens and methods for manufacturing and operating a liquid lens can be provided. Although a single liquid lens is described and illustrated in the drawing figures, unless otherwise noted, it is to be understood that, in some embodiments, a plurality of liquid lenses can be provided, and one or more of the plurality of liquid lenses can include the same or similar features as the single liquid lens, without departing from the scope of the disclosure.

For example, in some embodiments, the plurality of liquid lenses can be manufactured more efficiently (e.g., simultaneously, faster, less expensively, in parallel) as an array (e.g., based on wafer scale fabrication) including the plurality of liquid lenses. For example, as compared to manufacturing a plurality of single liquid lenses manually (e.g., by human hand) or individually and separately, in some embodiments, an array including the plurality of liquid lenses can be manufactured automatically by a micro-electro-mechanical system including a controller (e.g., computer, robot), thereby increasing one or more of the manufacturing efficiency, the rate of production, the scalability, and the repeatability of the manufacturing process.

Moreover, in some embodiments, for example, after manufacturing the array including the plurality of liquid lenses, one or more liquid lenses can be separated from the array (e.g., singulation) and provided as a single liquid lens in accordance with embodiments of the disclosure. In some embodiments, whether manufactured as a single liquid lens or an array including a plurality of liquid lenses, the liquid lens of the present disclosure can be provided, manufactured, operated, and employed in accordance with embodiments of the disclosure without departing from the scope of the disclosure.

The present disclosure relates generally to a liquid lens and methods for manufacturing and operating a liquid lens. Apparatus including a liquid lens including a conductive layer and an insulative layer as well as methods for manufacturing and operating a liquid lens including a conductive layer and an insulative layer will now be described by way of exemplary embodiments in accordance with the disclosure.

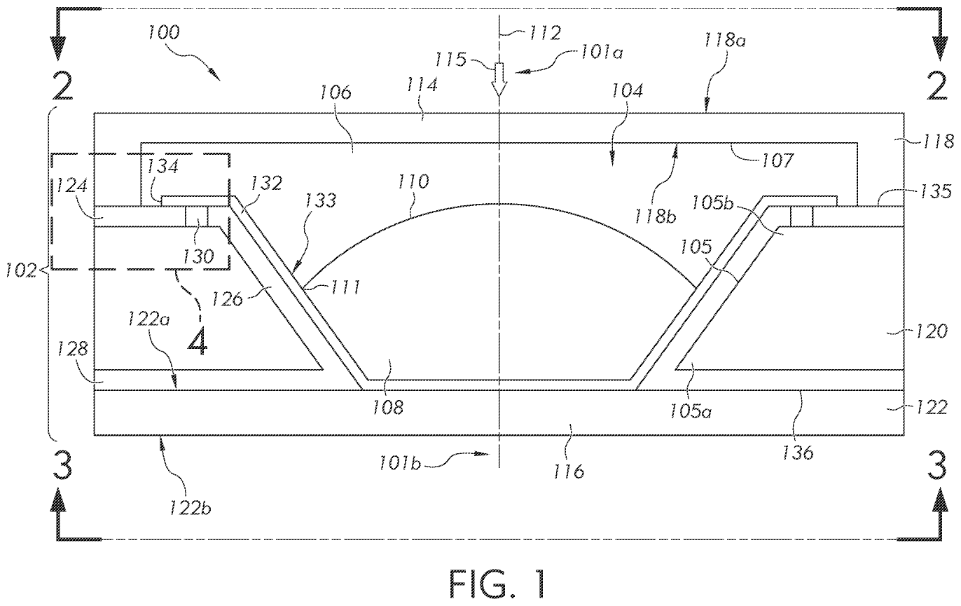

As schematically illustrated, FIG. 1 shows a schematic cross-sectional view of an exemplary embodiment of a liquid lens 100 in accordance with embodiments of the disclosure. For visual clarity, cross-hatching of features of the cross-sectional view of FIG. 1 is omitted. In some embodiments, the liquid lens 100 can include a lens body 102 and a cavity 104 defined (e.g., formed) in the lens body 102. In some embodiments, the liquid lens 100 can include a plurality of components that, either alone or in combination, define the lens body 102. Unless otherwise noted, in some embodiments, a variety of shapes and sizes of the lens body 102 can be provided without departing from the scope of the disclosure. In some embodiments, the lens body 102 can define a circular shape (shown), although other shapes including but not limited to, rectangular, square, oval, cylindrical, cuboidal, or other two-dimensional or three-dimensional geometric shape. Likewise, in some embodiments, the lens body 102 can define dimensions on the order of centimeters, millimeters, micrometers, or other sizes suitable for lenses, including but not limited to, camera lenses for hand-held electronic devices or other electronic devices including one or more lenses in accordance with embodiments of the disclosure.

For example, in some embodiments, the liquid lens 100 can include a first outer layer 118, an intermediate layer 120, and a second outer layer 122 that, either alone or in combination, define the lens body 102. In some embodiments, the intermediate layer 120 can be disposed between the first outer layer 118 and the second outer layer 122 with the cavity 104 defined, at least in part, by an internal space (e.g., void, volume) provided in the intermediate layer 120 and bounded on a first side (e.g., an object side 101a) of the liquid lens 100 by the first outer layer 118, and bounded on a second side (e.g., an image side 101b) of the liquid lens 100 by the second outer layer 122. In some embodiments, the intermediate layer 120 can include (e.g., be manufactured from) one or more of a metallic material, polymeric material, glass material, ceramic material, or glass-ceramic material. Additionally, in some embodiments, the intermediate layer 120 can include (e.g., be manufactured to include) a bore 105 (e.g., aperture) forming a space defining, at least in part, a portion of the cavity 104 between the first outer layer 118 and the second outer layer 122.

In some embodiments, the bore 105 formed in the intermediate layer 120 can include a narrow end 105a and a wide end 105b. Unless otherwise noted, in some embodiments, the narrow end 105a can define a smaller dimension (e.g., diameter) of the bore 105 relative to a corresponding dimension (e.g., diameter) defined by the wide end 105b of the bore 105. For example, in some embodiments, the bore 105 and the cavity 104 can be tapered such that a cross-sectional area of the bore 105 and the cavity 104 decrease along an optical axis 112 of the liquid lens 100 in a direction extending from the object side 101a of the liquid lens 100 to the image side 101b of the liquid lens 100. Additionally, in some embodiments (not shown), the bore 105 and the cavity 104 can be tapered such that a cross-sectional area of the bore 105 and the cavity 104 increase along the optical axis 112 in a direction extending from the image side 101b of the liquid lens 100 to the object side 101a of the liquid lens 100. Moreover, in some embodiments (not shown), the bore 105 and the cavity 104 can be non-tapered such that a cross-sectional area of the bore 105 and the cavity 104 are substantially constant along the optical axis 112.

In some embodiments, the lens body 102 can include a first window 114 defined between a first major surface 118a of the first outer layer 118 and a second major surface 118b of the first outer layer 118. Similarly, in some embodiments, the lens body 102 can include a second window 116 defined between a first major surface 122a of the second outer layer 122 and a second major surface 122b of the second outer layer 122. Thus, in some embodiments, at least a portion of the first outer layer 118 can define the first window 114, and at least a portion of the second outer layer 122 can define the second window 116. In some embodiments, the first window 114 can define the object side 101a of the liquid lens 100, and the second window 116 can define the image side 101b of the liquid lens 100. For example, in some embodiments, the first major surface 118a of the first outer layer 118 can face the object side 101a of the liquid lens 100, and the second major surface 122b of the second outer layer 122 can face the image side 101b of the liquid lens 100. Thus, in some embodiments, the cavity 104 can be disposed between the first window 114 and the second window 116. For example, in some embodiments, the second major surface 118b of the first outer layer 118 can be spaced a non-zero distance from and face the first major surface 122a of the second outer layer 122. Accordingly, in some embodiments, the cavity 104 can be defined, either alone or in combination, as at least a portion of the space (e.g., volume) between the second major surface 118b of the first outer layer 118 and the first major surface 122a of the second outer layer 122, including the space defined by the bore 105 formed in the intermediate layer 120.

Moreover, although the lens body 102 of the liquid lens 100 is schematically illustrated as including the first outer layer 118, the intermediate layer 120, and the second outer layer 122, other components and configurations can be provided in further embodiments, without departing from the scope of the disclosure. For example, in some embodiments, one or more of the outer layers 118, 122 can be omitted, and the bore 105 in the intermediate layer 120 can be provided as a blind hole that does not extend entirely through the intermediate layer 120. Likewise, although a first portion of the cavity 104 is schematically illustrated as being disposed within the recess 107 of the first outer layer 118, other embodiments can be provided in further embodiments, without departing from the scope of the disclosure. For example, in some embodiments, the recess 107 can be omitted, and the first portion of the cavity 104 can be disposed within the bore 105 in the intermediate layer 120. Thus, in some embodiments, the first portion of the cavity 104 can be defined as an upper portion of the bore 105, and a second portion of the cavity 104 can be defined as a lower portion of the bore 105. In some embodiments, the first portion of the cavity 104 can be disposed partially within the bore 105 of the intermediate layer 120 and partially outside the bore 105.

In some embodiments, the cavity 104 can include the first portion (e.g., headspace) and the second portion (e.g., base region). For example, in some embodiments, the first portion of the cavity 104 can be defined, based at least in part, as a space (e.g., volume) provided by a recess 107 in the first outer layer 118. In addition or alternatively, in some embodiments, the first portion of the cavity 104 can be defined, based at least in part, as a space provided by at least a portion of the bore 105 formed in the intermediate layer 120 bounded by the first outer layer 118 and the second portion. Likewise, in some embodiments, the second portion of the cavity 104 can be defined, based at least in part, as a space (e.g., volume) provided by at least a portion of the bore 105 formed in the intermediate layer 120 bounded by the second outer layer 122 and the first portion.

In some embodiments, the cavity 104 can be sealed (e.g., hermetically sealed) within the lens body 102. For, example, in some embodiments, the first outer layer 118 can be bonded to the intermediate layer 120 at a first bond 135. In addition or alternatively, in some embodiments, the second outer layer 122 can be bonded to the intermediate layer 120 at a second bond 136. In some embodiments, at least one of the first bond 135 and the second bond 136 can include one or more of an adhesive bond, a laser bond (e.g., a laser weld), or other suitable bond to seal (e.g., hermetically seal) the first outer layer 118 to the intermediate layer 120 at bond 135 and to seal (e.g., hermetically seal) the second outer layer 122 to the intermediate layer 120 at bond 136. Accordingly, in some embodiments, the cavity 104 formed in the lens body 102, including contents disposed within the cavity 104, can be hermetically sealed and isolated with respect to an environment in which the liquid lens 100 may be employed.

In some embodiments, the liquid lens 100 can include a conductive layer 128 and an insulative layer 132. In some embodiments, at least a portion of the conductive layer 128 and at least a portion of the insulative layer 132 can be disposed within the cavity 104. For example, in some embodiments, the conductive layer 128 can include an electrically conductive coating applied to the intermediate layer 120. In some embodiments, the conductive layer 128 can include (e.g., be manufactured from) one or more of an electrically conductive metallic material, an electrically conductive polymer material, or other suitable electrically conductive material. In addition or alternatively, in some embodiments, the conductive layer 128 can include a single layer or a plurality of layers, at least one or more of which can be electrically conductive.

Similarly, in some embodiments, the insulative layer 132 can include an electrically insulative (e.g., dielectric) coating applied to the intermediate layer 120. For example, in some embodiments, the insulative layer 132 can include an electrically insulative coating applied to at least a portion of the conductive layer 128 and to at least a portion of the first major surface 122a of the second outer layer 122. In some embodiments, the insulative layer 132 can include (e.g., be manufactured from) one or more of polytetrafluoroethylene (PTFE) material, parylene material, or other suitable polymeric or non-polymeric electrically insulative material. In addition or alternatively, in some embodiments, the insulative layer 132 can include a single layer or a plurality of layers, at least one or more of which can be electrically insulative. Moreover, in some embodiments, the insulative layer 132 can include (e.g., be manufactured from) a hydrophobic material. In addition or alternatively, in some embodiments the insulative layer 132 can include (e.g., be manufactured from) a hydrophilic material including a surface coating or surface treatment providing an exposed surface 133 of the insulative layer 132 in contact with, for example, the first liquid 106 and the second liquid 108 with hydrophobic material properties.

In some embodiments, the conductive layer 128 can be applied to the intermediate layer 120 prior to bonding at least one of the first outer layer 118 to the intermediate layer 120 (e.g., bond 135) and the second outer layer 122 to the intermediate layer 120 (e.g., bond 136). Likewise, in some embodiments, the insulative layer 132 can be applied to the intermediate layer 120 prior to bonding at least one of the first outer layer 118 to the intermediate layer 120 and the second outer layer 122 to the intermediate layer 120. In some embodiments, the insulative layer 132 can be applied to at least a portion of the conductive layer 128 and to at least a portion of the first major surface 122a of the second outer layer 122 prior to bonding at least one of the first outer layer 118 to the intermediate layer 120 and the second outer layer 122 to the intermediate layer 120. Alternatively, in some embodiments, the insulative layer 132 can be applied to at least a portion of the conductive layer 128 and to at least a portion of the first major surface 122a of the second outer layer 122 after bonding the second outer layer 122 to the intermediate layer 120 and prior to bonding the first outer layer 118 to the intermediate layer 120. Thus, in some embodiments, the insulative layer 132 can cover at least a portion of the conductive layer 128 and at least a portion of the first major surface 122a of the second outer layer 122 within the cavity 104.

In some embodiments, the conductive layer 128 can define at least one of a common electrode 124 and a driving electrode 126. For example, in some embodiments, the conductive layer 128 can be applied to substantially an entire surface of the intermediate layer 120 including a sidewall of the bore 105 prior to bonding at least one of the first outer layer 118 and the second outer layer 122 to the intermediate layer 120. Additionally, in some embodiments, after applying the conductive layer 128 to the intermediate layer 120, the conductive layer 128 can be segmented into one or more electrically isolated conductive elements including, but not limited to, the common electrode 124 and the driving electrode 126.

For example, in some embodiments, the liquid lens 100 can include a scribe 130 formed in the conductive layer 128 to isolate (e.g., electrically isolate) the common electrode 124 from the driving electrode 126. In some embodiments, the scribe 130 can include a gap (e.g., space) in the conductive layer 128. For example, in some embodiments, the scribe 130 can define a gap in the conductive layer 128 between the common electrode 124 and the driving electrode 126. In some embodiments, a dimension (e.g., width) of the scribe 130 can be about 5 μm (micrometers), about 10 μm, about 15 μm, about 20 μm, about 25 μm, about 30 μm, about 35 μm, about 40 μm, about 45 μm, about 50 μm, including all ranges and subranges therebetween.

Additionally, in some embodiments, a first liquid 106 and a second liquid 108 can be disposed within the cavity 104. For example, in some embodiments, at least a quantity (e.g., volume) of the first liquid 106 can be disposed in at least a portion of the first portion of the cavity 104. Likewise, in some embodiments, at least a quantity (e.g., volume) of the second liquid 108 can be disposed in at least a portion of the second portion of the cavity 104. For example, in some embodiments, substantially all or a predetermined amount of a quantity of the first liquid 106 can be disposed in the first portion of the cavity 104, and substantially all or a predetermined amount of a quantity of the second liquid 108 can be disposed in the second portion of the cavity 104.

As noted, in some embodiments, the cavity 104 can be sealed (e.g., hermetically sealed) within the lens body 102. Accordingly, in some embodiments, the first liquid 106 and the second liquid 108 can be disposed within the cavity 104 prior to hermetically sealing the lens body 102 to, thereby, define the hermetically sealed cavity 104 including the first liquid 106 and the second liquid 108 disposed within the hermetically sealed cavity 104.

For example, in some embodiments, the second outer layer 122 can be bonded to the intermediate layer 120 at the second bond 136, and then the first liquid 106 and the second liquid 108 can be added to the region of the cavity 104 provided by bonding the second outer layer 122 and the intermediate layer 120 at the second bond 136. In some embodiments, bonding the second outer layer 122 to the intermediate layer 120 at the second bond 136 can seal (e.g., hermetically seal) the second outer layer 122 to the intermediate layer 120 at the bond 136. Additionally, in some embodiments, after adding the first liquid 106 and the second liquid 108 to the region of the cavity 104, the first outer layer 118 can then be bonded to the intermediate layer 120 at the first bond 135. In some embodiments, bonding the first outer layer 118 and the intermediate layer 120 at the first bond 135 can seal (e.g., hermetically seal) the first outer layer 118 to the intermediate layer 120 at the first bond 135. Accordingly, in some embodiments, the cavity 104 formed in the lens body 102, including the first liquid 106 and the second liquid 108 disposed within the cavity 104, can be hermetically sealed and isolated with respect to an environment in which the liquid lens 100 may be employed.

Alternatively, in some embodiments, the first outer layer 118 can be bonded to the intermediate layer 120 at the first bond 135, and then the first liquid 106 and the second liquid 108 can be added to the region of the cavity 104 provided by bonding the first outer layer 118 to the intermediate layer 120 at the first bond 135. In some embodiments, bonding the first outer layer 118 to the intermediate layer 120 at the first bond 135 can seal (e.g., hermetically seal) the first outer layer 118 to the intermediate layer 120 at the first bond 135. Additionally, in some embodiments, after adding the first liquid 106 and the second liquid 108 to the region of the cavity 104, the second outer layer 122 can then be bonded to the intermediate layer 120 at the second bond 136. In some embodiments, bonding the second outer layer 122 and the intermediate layer 120 at the second bond 136 can seal (e.g., hermetically seal) the second outer layer 122 and the intermediate layer 120 at the second bond 136. Accordingly, in some embodiments, the cavity 104 formed in the lens body 102, including the first liquid 106 and the second liquid 108 disposed within the cavity 104, can be hermetically sealed and isolated with respect to an environment in which the liquid lens 100 may be employed.

Additionally, in some embodiments, the first liquid 106 can be a low index, polar liquid or a conducting liquid (e.g., water). In addition or alternatively, in some embodiments, the second liquid 108 can be a high index, non-polar liquid or an insulating liquid (e.g., oil). Moreover, in some embodiments, the first liquid 106 and the second liquid 108 can be immiscible with respect to each other and can have different refractive indices (e.g., water and oil). Thus, in some embodiments, the boundary (e.g., meniscus) of the first liquid 106 and the second liquid 108 can define an interface 110. In some embodiments, the interface 110 defined between the first liquid 106 and the second liquid 108 can define (e.g., include one or more characteristics of) a lens (e.g., a liquid lens). In some embodiments, a perimeter 111 of the interface 110 (e.g., an edge of the interface 110 in contact with a sidewall of the bore 105 of the cavity 104) can be disposed in the first portion of the cavity 104 and/or in the second portion of the cavity 104 in accordance with embodiments of the disclosure. Additionally, in some embodiments, the first liquid 106 and the second liquid 108 can have substantially the same density. In some embodiments, providing the first liquid 106 and the second liquid 108 with substantially the same density can help to avoid changes in a shape of the interface 110 based at least in part on, for example, gravitational forces acting on the first liquid 106 and the second liquid 108 with respect to a physical orientation of the liquid lens 100 relative to the direction of gravity.

In some embodiments, within the cavity 104, the common electrode 124 can be in electrical communication with the first liquid 106. Additionally, in some embodiments, the driving electrode 126 can be disposed on a sidewall of the bore 105 within the cavity 104 and can be electrically insulated from the first liquid 106 and the second liquid 108, for example, by the insulative layer 132. For example, in some embodiments, within the cavity 104, the insulative layer 132 can cover one or more of the driving electrode 126 of the conductive layer 128, at least a portion of the first major surface 122a of the second outer layer 122, the scribe 130, and at least a portion of the common electrode 124 of the conductive layer 128. Additionally, in some embodiments, at least a portion of the common electrode 124 can be uncovered with respect to the insulative layer 132 to expose a non-insulated portion of the common electrode 124 to the cavity 104, thereby providing the non-insulated portion of the common electrode 124 in electrical communication with the first liquid 106. For example, in some embodiments, the insulative layer 132 can include a perimeter or boundary 134 (e.g., edge, outer edge) defining a location corresponding to the uncovered portion of the common electrode 124 with respect to the insulative layer 132.

Thus, in some embodiments, within the cavity 104, the first liquid 106 can be in electrical communication with the common electrode 124 of the conductive layer 128, the second liquid 108 can be electrically isolated from the common electrode 124 by the insulative layer 132, and the first liquid 106 and the second liquid 108 can be electrically isolated from the driving electrode 126 of the conductive layer 128 by the insulative layer 132. Moreover, in some embodiments, the exposed surface 133 of the insulative layer 132 can be in contact with the first liquid 106 and the second liquid 108.

Accordingly, in some embodiments, the liquid lens defined as the interface 110 between the first liquid 106 and the second liquid 108 can be adjusted based, at least in part, by electrowetting. In some embodiments, electrowetting can be defined as controlling the wettability of the first liquid 106 with respect to the exposed surface 133 of the insulative layer 132 by controlling a voltage of the common electrode 124 and the driving electrode 126. For example, in some embodiments, different voltages can be supplied to the common electrode 124 and to the driving electrode 126 to define one or more electric fields to which the first liquid 106 and the second liquid 108 can be subjected. Accordingly, in some embodiments, the one or more electric fields to which the first liquid 106 and the second liquid 108 can be subjected can be employed to change a shape (e.g., profile) of the interface 110 based, at least in part, by electrowetting.

In some embodiments, a controller (not shown) can be configured to provide a first voltage (e.g., common voltage) to the common electrode 124 and, therefore, to the first liquid 106 in electrical communication with the common electrode 124. In some embodiments, the controller can be configured to provide a second voltage (e.g., driving voltage) to the driving electrode 126 electrically isolated from the first liquid 106 and the second liquid 108 by the insulative layer 132. In some embodiments, the voltage difference between the common electrode 124 (including the first liquid 106) and the driving electrode 126 can define a shape of the interface 110 in accordance with embodiments of the disclosure. Moreover, in some embodiments, the common voltage and/or the driving voltage can include an oscillating voltage signal (e.g., a square wave, a sine wave, a triangle wave, a sawtooth wave, or another oscillating voltage signal). In some of such embodiments, the voltage differential between the common electrode 124 and the driving electrode 126 can include a root mean square (RMS) voltage differential. In addition or alternatively, in some embodiments, the voltage differential between common electrode 124 and the driving electrode 126 can be manipulated based on a pulse width modulation (e.g., by manipulating a duty cycle of the differential voltage signal).

In some embodiments, controlling the voltage of the common electrode 124 (including the first liquid 106) and the driving electrode 126 can increase or decrease the wettability of the first liquid 106 with respect to the exposed surface 133 of the insulative layer 132 within the cavity 104 and, therefore, change the shape of the interface 110. For example, in some embodiments, hydrophobic characteristics of the exposed surface 133 of the insulative layer 132 can help to maintain the second liquid 108 within the second portion of the cavity 104 based on attraction between the non-polar second liquid 108 and the hydrophobic exposed surface 133. Likewise, in some embodiments, hydrophobic characteristics of the exposed surface 133 of the insulative layer 132 can enable the perimeter 111 of the interface 110 to move along the hydrophobic exposed surface 133 based, at least in part, on an increase or decrease of the wettability of the first liquid 106 with respect to the exposed surface 133 of the insulative layer 132 within the cavity 104. Accordingly, in some embodiments, based at least in part on electrowetting, one or more features of the disclosure can be provided, either alone or in combination, to move the perimeter 111 of the interface 110 along the hydrophobic exposed surface 133 and, therefore, control (e.g., maintain, change, adjust) the shape of the liquid lens defined as the interface 110 between the first liquid 106 and the second liquid 108 within the cavity 104 of the liquid lens 100 in accordance with embodiments of the disclosure.

In some embodiments, controlling the shape of the interface 110 can control one or more of a zoom and a focal length or focus (e.g., at least one of a diopter and a tilt) of the liquid lens defined by the interface 110 of the liquid lens 100. For example, in some embodiments, controlling the focal length or focus, by controlling the shape of the interface 110, can enable the liquid lens 100 to perform an autofocus function. In addition or alternatively, in some embodiments, controlling the shape of the interface 110 can tilt the interface 110 relative to the optical axis 112 of the liquid lens 100. For example, in some embodiments, tilting the interface 110 relative to the optical axis 112 can enable the liquid lens 100 to perform an optical image stabilization (OIS) function. Additionally, in some embodiments, the shape of the interface 110 can be controlled without physical movement of the liquid lens 100 relative to, for example, one or more of an image sensor, a fixed lens, a lens stack, a housing, and other components of a camera module in which the liquid lens 100 can be incorporated and employed.

In some embodiments, image light (represented by arrow 115) can enter the object side 101a of the liquid lens 100 through the first window 114, be refracted at the interface 110 between the first liquid 106 and the second liquid 108 defining the liquid lens, and exit the image side 101b of the liquid lens 100 through the second window 116. In some embodiments, the image light 115 can travel in a direction extending along the optical axis 112. Thus, in some embodiments, at least one of the first outer layer 118 and the second outer layer 122 can include an optical transparency to enable passage of the image light 115 into, through, and out of the liquid lens 100 in accordance with embodiments of the disclosure. For example, in some embodiments, at least one of the first outer layer 118 and the second outer layer 122 can include (e.g., be manufactured from) one or more optically transparent materials including, but not limited to, a polymeric material, a glass material, a ceramic material, or a glass-ceramic material. Likewise, in some embodiments, the insulative layer 132 can include an optical transparency to enable passage of the image light 115 from the interface 110 through the insulative layer 132 and into the second window 116. Additionally, in some embodiments, the image light 115 can pass through the bore 105 formed in the intermediate layer 120, and the intermediate layer 120 can, therefore, optionally include an optical transparency.

In some embodiments, outer surfaces of the liquid lens 100 can be planar as compared to being non-planar (e.g., curved) as with, for example, outer surfaces of a fixed lens (not shown). For example, in some embodiments, as schematically illustrated, at least one of the first major surface 118a and the second major surface 118b of the first outer layer 118 and at least one of the first major surface 122a and the second major surface 122b of the second outer layer 122 can be substantially planar. Accordingly, in some embodiments, the liquid lens 100 can include planar outer surfaces while, nonetheless, operating and functioning as a curved lens by, for example, refracting image light 115 passing through the interface 110 which can include a curved (e.g., concave, convex) shape in accordance with embodiments of the disclosure. However, in some embodiments, outer surfaces of at least one of the first outer layer 118 and the second outer layer 122 can be non-planar (e.g., curved, concave, convex) without departing from the scope of the disclosure. Thus, in some embodiments, the liquid lens 100 can include an integrated fixed lens or other optical components (e.g., filters, lens, protective coatings, scratch resistant coatings) provided, alone or in combination with the liquid lens defined as the interface 110, to provide a liquid lens 100 in accordance with embodiments of the disclosure.

In some embodiments, one or more control devices (not shown) including, but not limited to, a controller, a driver, a sensor (e.g., capacitance sensor, temperature sensor), or other mechanical, electronic, or electro-mechanical component of a lens or camera system, can be provided in accordance with embodiments of the disclosure to, for example, operate one or more features of the liquid lens 100. For example, in some embodiments, a control device can be provided and electrically connected to the conductive layer 128 to, for example, operate one or more features of the liquid lens 100. In some embodiments, a control device can be provided and electrically connected to the common electrode 124 to, for example, apply and control the first voltage (e.g., common voltage) supplied to the common electrode 124. Similarly, in some embodiments, a control device can be provided and electrically connected to the driving electrode 126 to, for example, apply and control the second voltage (e.g., driving voltage) supplied to the driving electrode 126.

Accordingly, in some embodiments, the bond 135 between the first outer layer 118 and the intermediate layer 120 can be configured to provide electrical continuity across the bond 135 at one or more locations to enable control of the common electrode 124 defined within the sealed cavity 104 based on one or more electrical signals provided (e.g., by a control device) to the conductive layer 128 (e.g., the common electrode 124) defined outside of the sealed cavity 104. Likewise, in some embodiments, the bond 136 between the second outer layer 122 and the intermediate layer 120 can be configured to provide electrical continuity across the bond 136 at one or more locations to enable control of the driving electrode 126 defined within the sealed cavity 104 based on one or more electrical signals provided (e.g., by a control device) to the conductive layer 128 (e.g., the driving electrode 126) defined outside of the sealed cavity 104. Thus, in some embodiments, based at least on the scribe 130 electrically isolating the common electrode 124 and the driving electrode 126, separate and independent electrical signals can be provided (e.g., by one or more control devices) to each of the common electrode 124 and the driving electrode 126 in accordance with embodiments of the disclosure.

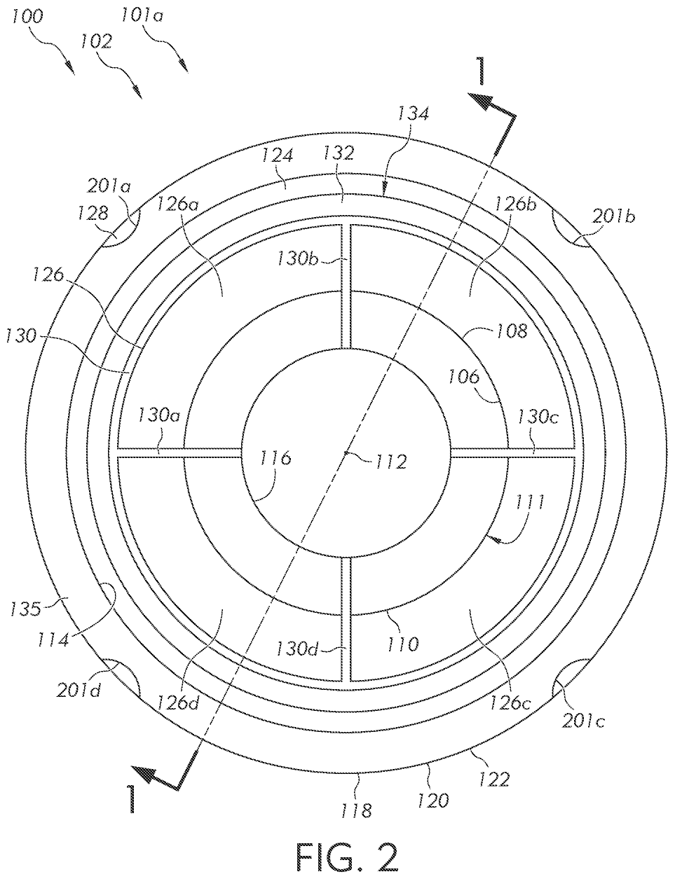

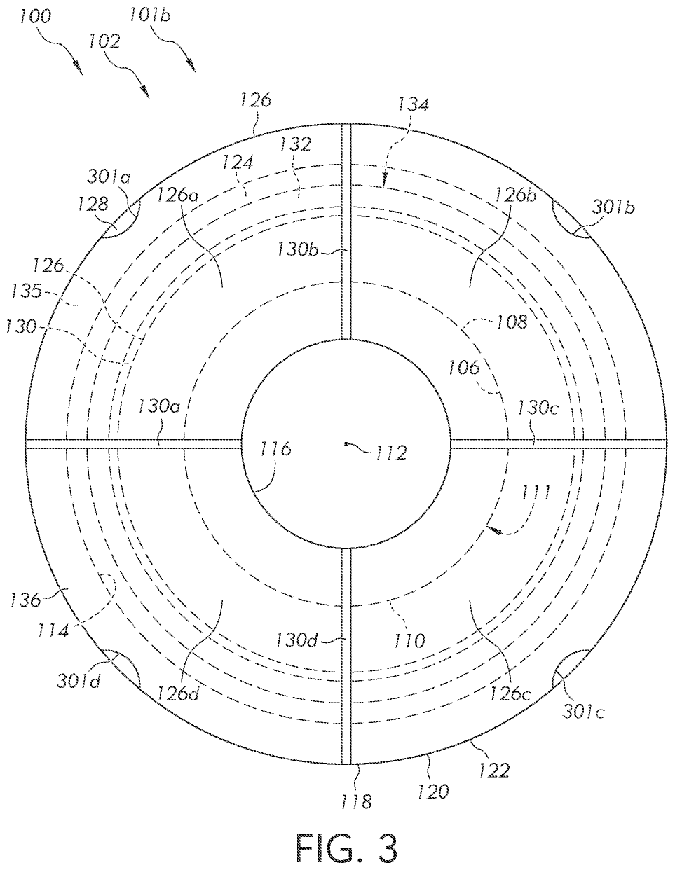

FIG. 2 schematically illustrates a top (e.g., plan) view of the liquid lens 100 taken along line 2-2 of FIG. 1 representing a view facing the first outer layer 118 and looking into the cavity 104 from the object side 101a through the first window 114. Although FIG. 2 illustrates the liquid lens 100 as having a circular perimeter, other embodiments are included in this disclosure. For example, in other embodiments, the perimeter of the liquid lens is triangular, rectangular, elliptical, or another polygonal or non-polygonal shape. Likewise, FIG. 3 schematically illustrates a bottom view of the liquid lens 100 taken along line 3-3 of FIG. 1 representing a view facing the second outer layer 122 and looking into the cavity 104 from the image side 101b through the second window 116. For clarity, in FIG. 2 and FIG. 3, the entire liquid lens 100 is schematically illustrated despite FIG. 1 providing an exemplary cross-sectional view of the liquid lens 100. For example, in some embodiments, FIG. 1 can be understood to show an exemplary cross-sectional view of the liquid lens 100 taken along line 1-1 of FIG. 2 in accordance with embodiments of the disclosure.

As shown in FIG. 2, in some embodiments, the liquid lens 100 can include one or more first cutouts 201a, 201b, 201c, 201d in the first outer layer 118. For example, in some embodiments, four first cutouts 201a, 201b, 201c, 201d can be provided, although more or less first cutouts can be provided in further embodiments without departing form the scope of the disclosure. In some embodiments, the first cutouts 201a, 201b, 201c, 201d can define respective portions of the lens body 102 at which the first outer layer 118 can be removed, machined, or manufactured to expose a corresponding portion of the common electrode 124 of the conductive layer 128. Thus, in some embodiments, the first cutouts 201a, 201b, 201c, 201d can provide electrical contact locations to enable electrical connection of the common electrode 124 to a controller, a driver, or other mechanical, electronic, or electro-mechanical component of a lens or camera system, in accordance with embodiments of the disclosure.

As shown in FIG. 3, in some embodiments, the liquid lens 100 can include one or more second cutouts 301a, 301b, 301c, 301d in the second outer layer 122. For example, in some embodiments, four second cutouts 301a, 301b, 301c, 301d can be provided, although more or less second cutouts can be provided in further embodiments without departing form the scope of the disclosure. In some embodiments, the second cutouts 301a, 301b, 301c, 301d can define respective portions of the lens body 102 at which the second outer layer 122 can be removed, machined, or manufactured to expose a corresponding portion of the driving electrode 126 of the conductive layer 128. Thus, in some embodiments, the second cutouts 301a, 301b, 301c, 301d can provide electrical contact locations to enable electrical connection of the driving electrode 126 to a controller, a driver, or other mechanical, electronic, or electro-mechanical component of a lens or camera system, in accordance with embodiments of the disclosure.

Moreover, as shown in FIG. 2 and FIG. 3, in some embodiments, the driving electrode 126 of the conductive layer 128 can include a plurality of driving electrode segments 126a, 126b, 126c, 126d. In some embodiments, each of the driving electrode segments 126a, 126b, 126c, 126d can be electrically isolated from the common electrode 124 by the scribe 130 and electrically isolated from each other by respective scribes 130a, 130b, 103c, 130d. In some embodiments the scribes 130a, 130b, 103c, 130d can extend from the scribe 130 along the bore 105 of the intermediate layer 120 from the wide end 105b to the narrow end 105a (FIG. 2) and extend underneath the intermediate layer 120 onto a back side of the intermediate layer 120 (FIG. 3). In some embodiments, different driving voltages can be supplied to one or more of the driving electrode segments 126a, 126b, 126c, 126d to tilt the interface 110 of the liquid lens 100 about the optical axis 112, thereby providing, for example, optical image stabilization (OIS) functionality to the liquid lens 100. For example, in some embodiments, based at least on the electrical isolation provided by the scribes 130a, 130b, 130c, 130d in the conductive layer 128, the second cutouts 301a, 301b, 301c, 301d can respectively electrically communicate with each of the driving electrode segments 126a, 126b, 126c, 126d independently and separately to supply different driving voltages to one or more of the driving electrode segments 126a, 126b, 126c, 126d in accordance with embodiments of the disclosure.

In addition or alternatively, in some embodiments, the same driving voltage can be supplied to each driving electrode segment 126a, 126b, 126c, 126d to maintain the interface 110 of the liquid lens 100 in a substantially spherical orientation about the optical axis 112, thereby providing, for example, autofocus functionality to the liquid lens 100. Moreover, although the driving electrode 126 is described as being segmented into four driving electrode segments 126a, 126b, 126c, 126d, in some embodiments, the driving electrode 126 can be divided into two, three, five, six, seven, eight, or more driving electrode segments without departing from the scope of the disclosure. Accordingly, in some embodiments, the number of second cutouts 301a, 301b, 301c, 301d can match the number of driving electrode segments 126a, 126b, 126c, 126d. Likewise, in some embodiments, depending on, for example, the number of driving electrode segments 126a, 126b, 126c, 126d, a corresponding number of scribes 130a, 130b, 130c, 130d can be formed in the conductive layer 128 to electrically isolate each of the driving electrode segments 126a, 126b, 126c, 126d in accordance with embodiments of the disclosure.

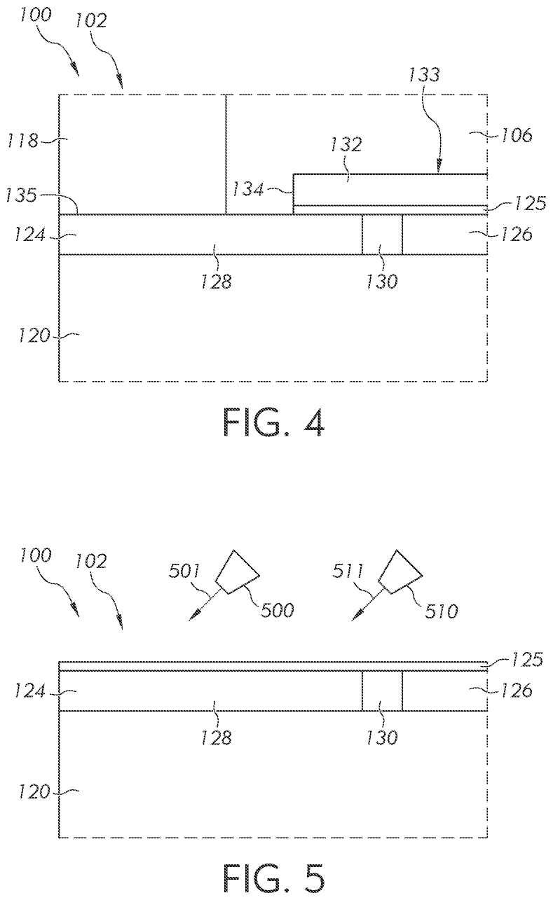

Methods of manufacturing the liquid lens 100 including the conductive layer 128 and the insulative layer 132 will now be described with respect to FIGS. 4-13 by way of exemplary embodiments and methods in accordance with the disclosure. For example, FIG. 4 shows an enlarged view of a portion of the liquid lens 100 taken at view 4 of FIG. 1, including the conductive layer 128 (e.g., common electrode 124, driving electrode 126) and the insulative layer 132 in accordance with embodiments of the disclosure. Unless otherwise noted, it is to be understood that, in some embodiments, one or more features or methods described with respect to the portion of the liquid lens 100 of FIG. 4 can be provided, either alone or in combination, to provide a conductive layer 128 and an insulative layer 132 in accordance with embodiments of the disclosure. For example, in some embodiments, one or more features or methods of the disclosure can provide the conductive layer 128, including the common electrode 124 and the driving electrode 126, and the insulative layer 132 with respect to features of the liquid lens 100 including the lens body 102 (e.g., the first outer layer 118, the intermediate layer 120, and the second outer layer 122) as well as within the cavity 104, thereby providing functionality with respect to operation of the interface 110 based at least in part on electrowetting without departing from the scope of the disclosure

FIG. 5 shows an exemplary method of manufacturing the liquid lens 100 of FIG. 4 including applying the conductive layer 128 (e.g., common electrode 124, driving electrode 126) in accordance with embodiments of the disclosure. For example, in some embodiments, a conductive material 501 from a conductive material supply device 500 (e.g., nozzle, sprayer, applicator, conductive material source or supply) can be applied to the intermediate layer 120 form the conductive layer 128 (e.g., the common electrode 124, the driving electrode 126) in accordance with embodiments of the disclosure. In some embodiments, the conductive layer 128 can include a plurality of conductive layers that can be applied to the intermediate layer 120 sequentially or simultaneously. Moreover, in some embodiments, the conductive layer 128 can include material (e.g., material having predetermined material properties) that can enable advantages for the methods of manufacturing the liquid lens 100.

Additionally, FIG. 5 shows an exemplary method of manufacturing the liquid lens 100 of FIG. 4 including applying an absorber material 511 from an absorber material supply device 510 (e.g., nozzle, sprayer, applicator, absorber material source or supply) to the conductive layer 128 to form an absorber layer 125 (e.g., electromagnetic absorber layer) in accordance with embodiments of the disclosure. In some embodiments, the absorber layer 125 can include a plurality of absorber layers that can be applied to the conductive layer 128 sequentially or simultaneously. In some embodiments the absorber layer 125 can be selected to include material (e.g., material having predetermined material properties) that can enable advantages for the methods of manufacturing the liquid lens 100.

For example, in some embodiment at least one of the conductive layer 128 and the absorber layer 125 can define a dark mirror structure. In some embodiments, for example, based at least on one or more material properties or other features of at least one of the conductive layer 128 and the absorber layer 125, the black mirror structure can enable advantages for the methods of manufacturing the liquid lens 100. For example, in some embodiments, a method of laser bonding (e.g., laser beam welding) the first outer layer 118 and the intermediate layer 120 at bond 135 can include providing a laser beam (e.g., concentrated heat source, ultra-violet laser beam, infrared laser beam) from a laser (e.g., laser device, laser source, ultra-violet laser device, infrared laser device) (not shown) to heat (e.g., locally heat) the dark mirror structure (e.g., at least one of the conductive layer 128 and the absorber layer 125) in accordance with embodiments of the disclosure.

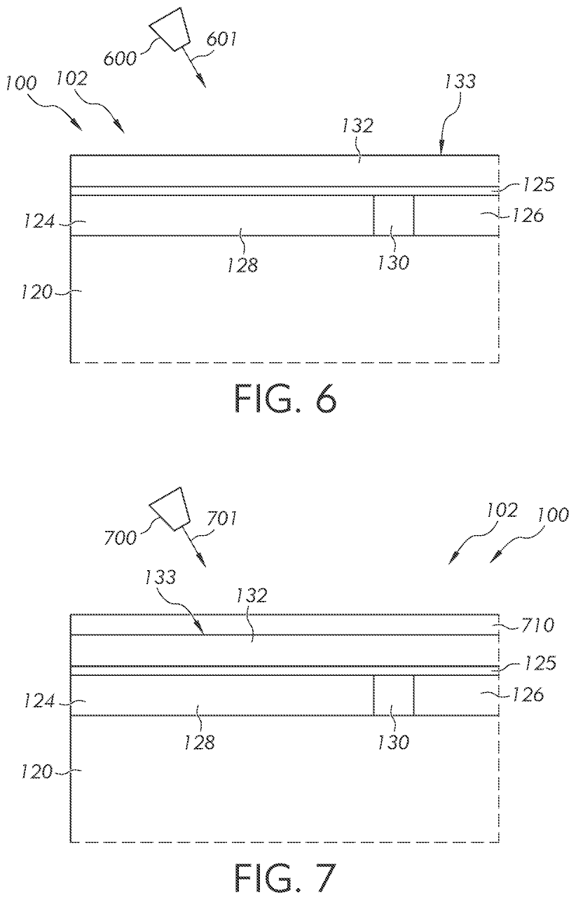

FIG. 6 shows an exemplary method of manufacturing the liquid lens 100 of FIG. 4 including applying the insulative layer 132. In some embodiments, the insulative layer 132 may be applied to the absorber layer 125 and the conductive layer 128 of FIG. 5 in accordance with embodiments of the disclosure. Alternatively, in some embodiments, the insulative layer 132 may be applied to the conductive layer 128 without being applied to the absorber layer 125, for example, in embodiments where the absorber layer 125 is not provided. As shown in FIG. 6, an insulative material 601 from an insulative material supply device 600 (e.g., nozzle, sprayer, applicator, insulative material source or supply) can be applied to the absorber layer 125 and the conductive layer 128 to provide the insulative layer 132 including the hydrophobic exposed surface 133 of the insulative layer 132 in accordance with embodiments of the disclosure. In embodiments without the absorber layer 125, the insulative material 601 from the insulative material supply device 600 may similarly be applied to the conductive layer 128 without being applied to an absorber layer. In some embodiments, the insulative layer 132 can include a plurality of insulative layers that can be applied to the conductive layer 128, or to the absorber layer 125 and/or the conductive layer 128 sequentially or simultaneously. In some embodiments, the insulative layer 132 can include material (e.g., material having predetermined material properties) that can enable advantages for the methods of manufacturing the liquid lens 100.

For purposes of the disclosure, unless otherwise noted, it is to be understood that the conductive layer 128 can include one or more scribes 130, 130a, 130b, 103c, 130d to electrically isolate the one or more of the common electrode 124 and the driving electrode 126, and the driving electrode segments 126a, 126b, 126c, 126d in accordance with embodiments of the disclosure. Additionally, in some embodiments, the conductive layer 128 and the insulative layer 132 can included one or more additional features to, for example, enable bonding, provide electrical conductivity, provide electrical isolation, or other mechanical or functional objectives without departing from the scope of the disclosure. Moreover, in some embodiments, the conductive layer 128 and the insulative layer 132 can have one or more of a variety of shapes and sizes, including shapes and sizes not explicitly disclosed in accordance with embodiments of the disclosure without departing from the scope of the disclosure.

Moreover, in some embodiments, methods of manufacturing the liquid lens 100 can include patterning the insulative layer 132 to, for example, selectively remove portions of the insulative layer 132 and expose (e.g., uncover) portions of the conductive layer 128.

In some embodiments, one or more features or methods of the disclosure can be employed to pattern the insulative layer 132 to expose a portion of the conductive layer 128 (e.g., the common electrode 124) and/or such that the first outer layer 118 and the intermediate layer 120 can be bonded (e.g., laser beam welded) at bond 135. Likewise, in some embodiments, one or more features or methods of the disclosure can be employed to pattern the insulative layer 132 to expose a portion of the conductive layer 128 (e.g., the common electrode 124) such that the common electrode 124 can be provided in electrical communication with the first fluid 106 within the cavity 104 as discussed above with respect to operation of the liquid lens 100. Thus, in some embodiments, one or more features or methods of the disclosure can be employed to pattern the insulative layer 132 to expose a portion of the conductive layer 128 while maintaining a portion of the insulative layer 132 to, for example, insulate the driving electrode 126 from the first fluid 106 and the second fluid 108 as discussed above with respect to operation of the liquid lens 100. Moreover, in some embodiments, one or more features or methods of the disclosure can be employed to pattern the insulative layer 132 to expose a portion of the conductive layer 128 while maintaining hydrophobic material properties of the exposed surface 133 of the insulative layer 132 to enable modulation of the shape of the interface 110 as discussed above with respect to operation of the liquid lens 100

Additionally, in some embodiments, one or more features or methods of the disclosure can be employed to pattern the insulative layer 132 to expose the conductive layer 128 and provide conductive pads at one or more of the first cutouts 201a, 201b, 201c, 201d in the first outer layer 118 and the second cutouts 301a, 301b, 301c, 301d in the second outer layer 122 for electrical contact and electrical connection in accordance with embodiments of the disclosure. Moreover, in some embodiments, one or more features or methods of the disclosure can be employed to pattern the insulative layer 132 to expose the conductive layer 128 in a MEMs wafer scale fabrication process, for example, prior to singulation of an individual liquid lens 100 from an array including a plurality of liquid lenses 100. Unless otherwise noted, it is to be understood that, in some embodiments, one or more features or methods of the disclosure can be employed to pattern the insulative layer 132 at a variety of locations to include a variety of shapes (e.g., patterns) including locations and shapes not explicitly disclosed.

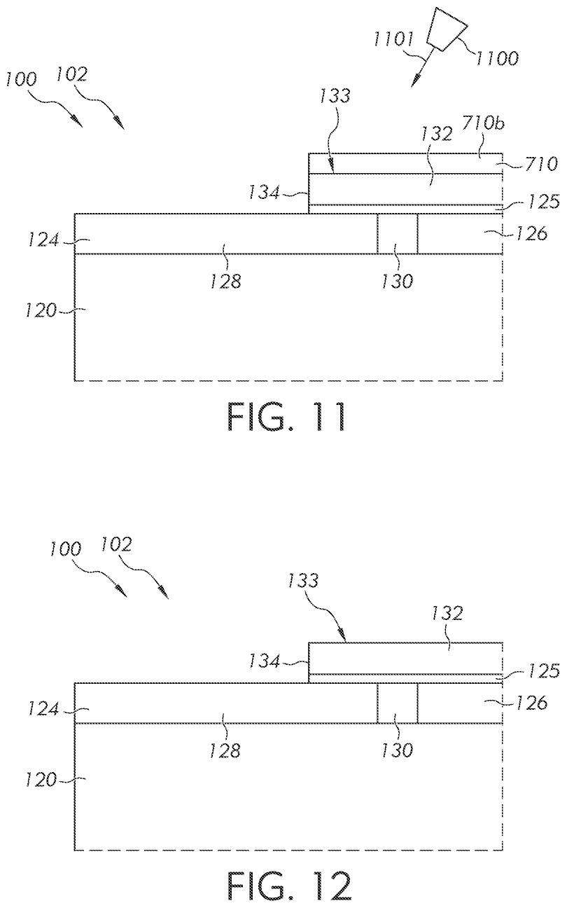

Exemplary methods of manufacturing the liquid lens 100 of FIG. 4 including methods of patterning the insulative layer 132 will now be described with respect to FIGS. 7-11 by way of exemplary embodiments and methods in accordance with the disclosure, including methods of patterning the insulative layer 132 based on photolithography. For example, in some embodiments, the insulative layer 132 can be patterned to modify a shape or profile (e.g., coverage) of the insulative layer 132 disposed on the conductive layer 128. In some embodiments, a lithography (e.g., photolithography) process can be employed in accordance with embodiments of the disclosure to pattern the insulative layer 132, thereby uncovering a portion of the conductive layer 128 based on modification (e.g., removal) of at least a portion of the insulative layer 132 from the conductive layer 128. For example, in some embodiments, based at least in part on a photolithography process, methods of the disclosure can be employed to modify the shape or profile of the insulative layer 132 on the conductive layer 128 from an initial shape or profile (e.g., the as-applied insulative layer 132 of FIG. 6) to a predetermined shape or profile (e.g., the patterned insulative layer 132 including a patterned periphery or boundary 134 of FIGS. 11-13).

FIG. 7 shows an exemplary method of manufacturing the liquid lens 100 of FIG. 4 including a method of patterning the insulative layer 132 of FIG. 6 in accordance with embodiments of the disclosure. As schematically illustrated, in some embodiments, the method can include applying a mask layer 710 to the hydrophobic exposed surface 133 of the insulative layer 132. For example, in some embodiments, a mask material 701 from a mask material supply device 700 (e.g., nozzle, sprayer, applicator, mask material source or supply) can be applied to the insulative layer 132 including the hydrophobic exposed surface 133 of the insulative layer 132 to provide the mask layer 710 in accordance with embodiments of the disclosure. In some embodiments, the mask layer 710 can include a plurality of layers that can be applied to the insulative layer 132 sequentially or simultaneously. In some embodiments, the mask layer 710 can include material (e.g., material having predetermined material properties) that enables advantages for the methods of manufacturing the liquid lens 100 including methods of patterning the insulative layer 132. For example, as discussed more fully below, in some embodiments, the mask layer 710 can include a photoresist material.

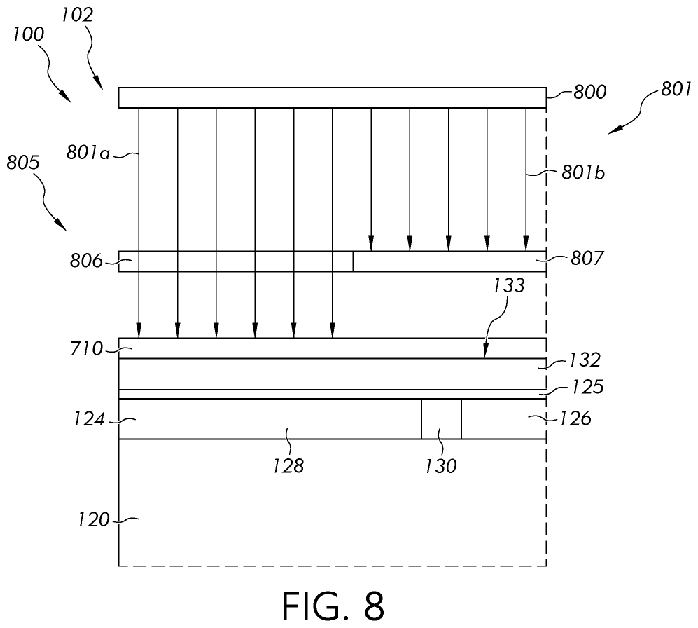

FIG. 8 shows an exemplary method of manufacturing the liquid lens 100 of FIG. 4 including the method of patterning the insulative layer 132 including positioning a pattern or mask 805 and exposing at least a portion of the mask layer 710 of FIG. 7 in accordance with embodiments of the disclosure. For example, in some embodiments, the method can include patterning the mask layer 710 using an electromagnetic source 800 (e.g., light source, light bulb, ultra-violet light, other exposure source). Additionally, in some embodiments, the pattern 805 can include a transparent region 806 and an opaque region 807. For purposes of the disclosure, unless otherwise noted, in some embodiments, the transparent region 806 of the pattern 805 can be defined as optically transparent to a wavelength of electromagnetic radiation 801 (e.g., light, light beam, intense light) emitted from the electromagnetic source 800. In some embodiments, the transparent region 806 of the pattern 805 can include material optically transparent to a wavelength of electromagnetic radiation 801 emitted from the electromagnetic source 800 and/or no material (e.g., empty space) optically transparent to a wavelength of electromagnetic radiation 801 emitted from the electromagnetic source 800. Likewise, for purposes of the disclosure, unless otherwise noted, in some embodiments, the opaque region 807 of the pattern 805 can be optically opaque to a wavelength of the electromagnetic radiation 801 emitted from the electromagnetic source 800.

In some embodiments, the pattern 805 can be positioned between the mask layer 710 and the electromagnetic source 800. For example, in some embodiments, the pattern 805 can be positioned to permit first electromagnetic radiation 801a from the electromagnetic source 800 to pass through the transparent region 806 of the pattern 805 and impinge on the mask layer 710 while preventing (e.g., blocking) second electromagnetic radiation 801b from the electromagnetic source 800 from impinging on the mask layer 710 by blocking the second electromagnetic radiation 801b from passing through the opaque region 807 of the pattern 805. In some embodiments, the profile (e.g., shape, size, orientation) of the pattern 805 can be defined based at least in part on the relative profiles (e.g., shape, size, orientation) of the transparent region 806 and the opaque region 807. For example, in some embodiments, the profile of the pattern 805 can correspond to a predetermined pattern defining a predetermined profile. Accordingly, in some embodiments, the insulative layer 132 can be patterned (e.g., based on the predetermined profile of the pattern 805) to define a corresponding shape or profile of the insulative layer 132 with respect to the conductive layer 128 in accordance with embodiments of the disclosure. Although not shown, other techniques can be provided to achieve the pattern without a mask layer 710 and/or without the pattern 805. For instance, laser patterning or other suitable patterning techniques may be incorporated in accordance with embodiments of the disclosure.

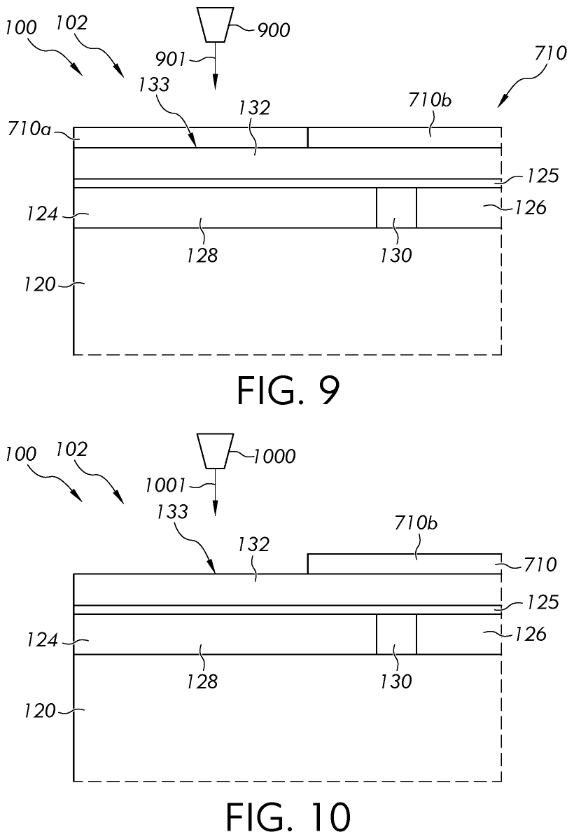

FIG. 9 shows an exemplary method of manufacturing the liquid lens 100 of FIG. 4 including the method of patterning the insulative layer 132 including developing at least an exposed portion 710a of the mask layer 710 of FIG. 8, thereby leaving an undeveloped portion 710b of the mask layer 710 in accordance with embodiments of the disclosure. For example, without intending to be bound by theory, in some embodiments, exposure of the mask layer 710 (e.g., exposed portion 710a) to electromagnetic radiation 801 (e.g., first electromagnetic radiation 801a), for example, through the transparent portion 806 of the pattern 805 can cause a chemical change that enables the exposed portion 710a of the mask layer 710 to be subsequently removed by a solution or developer. Conversely, without intending to be bound by theory, in some embodiments, blocking or preventing exposure of the mask layer 710 (e.g., unexposed portion 710b) from electromagnetic radiation 801 (e.g., second electromagnetic radiation 801b) can prevent the chemical change and, therefore, likewise prevent the unexposed portion 710b of the mask layer 710 from developing (e.g., being subsequently removed by the solution or developer).

Accordingly, in some embodiments, the patterning method can include applying a developer material 901 from a developer material supply device 900 (e.g., nozzle, sprayer, applicator, developer material source or supply) to the mask layer 710 to develop (e.g., remove) the exposed portion 710a of the mask layer 710 from a respective portion of the hydrophobic exposed surface 133 of the insulative layer 132 and maintain the unexposed portion 710b of the mask layer 710 (e.g., as undeveloped) on a respective portion of the hydrophobic exposed surface 133 of the insulative layer 132 in accordance with embodiments of the disclosure.

Unless otherwise noted, it is to be understood that positive photoresist and/or negative photoresist techniques may be employed, in some embodiments, without departing from the scope of the disclosure. For example, as shown, with respect to positive photoresist, the exposed portion 710a of the mask layer 710 can become soluble in the developer material 901 based at least on the chemical change of the exposed portion 710a of the mask layer 710 when exposed to the first electromagnetic radiation 801a. Conversely, with negative photoresist (not shown), an unexposed portion of the mask layer 710 can become soluble in the developer material 901 based on not being exposed to electromagnetic radiation. Thus, in some embodiments, the transparent portion 806 of the pattern 805 and the opaque portion 807 of the pattern 805 can be provided in a variety of configurations, shapes, and sizes, to selectively permit exposure of the mask layer 710 to electromagnetic radiation 801 and/or selectively block exposure of the mask layer 710 from electromagnetic radiation 801 in accordance with embodiments of the disclosure, without departing from the scope of the disclosure.

Moreover, in some embodiments, after developing the exposed portion 710a of the mask layer 710 to remove the exposed portion 710a from the hydrophobic exposed surface 133 of the insulative layer 132 with the developer 901, the undeveloped portion 710b of the mask layer 710 that was not removed from the hydrophobic exposed surface 133 of the insulative layer 132 by the developer 901 can act as a protective layer (e.g., mask) during subsequent processing. In some embodiments, the undeveloped portion 710b of the mask layer 710 that was not removed from the hydrophobic exposed surface 133 of the insulative layer 132 by the developer 901 can be heated (e.g., hard-baked) to solidify the undeveloped portion 710b and enhance the protective, masking capabilities of the undeveloped portion 710b of the mask layer 710 on the hydrophobic exposed surface 133 of the insulative layer 132 during subsequent processing. However, in some embodiments, the undeveloped portion 710b of the mask layer 710 that was not removed from the hydrophobic exposed surface 133 of the insulative layer 132 by the developer 901 can provide masking capabilities for the hydrophobic exposed surface 133 of the insulative layer 132 during subsequent processing without being heated and without departing from the scope of the disclosure.

FIG. 10 shows an exemplary method of manufacturing the liquid lens 100 of FIG. 4 including the method of patterning the insulative layer 132 including a method of etching the insulative layer 132 based on the undeveloped portion 710b of the mask layer 710 of FIG. 9 in accordance with embodiments of the disclosure. For example, in some embodiments, at least a portion of the insulative layer 132 from which the exposed portion 710a of the mask layer 710 was removed (e.g., developed) can be etched (e.g., removed) to uncover a respective portion of the conductive layer 128, as shown in FIG. 11.

For example, in some embodiments, referring back to FIG. 10, an etchant 1001 from an etchant supply device 1000 (e.g., nozzle, sprayer, applicator, etchant source or supply) can be applied to the at least a portion of the insulative layer 132 from which the exposed portion 710a of the mask layer 710 was removed in accordance with embodiments of the disclosure. In some embodiments, based at least on the step of applying the etchant 1001, the at least a portion of the insulative layer 132 to which the etchant 1001 was applied can, therefore, be removed to uncover a respective portion of the conductive layer 128. Likewise, the undeveloped portion 710b of the mask layer 710 can mask a corresponding portion of the insulative layer 132 with respect to the etchant 1001, thereby protecting the masked portion of the insulative layer 132 including the hydrophobic exposed surface 133 from the etchant 1001. In some embodiments, the etchant 1001 can include a liquid chemical agent (e.g., wet etch), a plasma chemical agent (e.g., dry etch), or ion milling, without departing from the scope of the disclosure.

FIG. 11 shows an exemplary method of manufacturing the liquid lens 100 of FIG. 4 including the method of patterning the insulative layer 132 including removing the undeveloped portion 710b of the mask layer 710 after the method of etching the insulative layer 132 based on the undeveloped portion 710b of the mask layer 710 of FIG. 10 in accordance with embodiments of the disclosure. For example, in some embodiments, a stripper material 1101 (e.g., mask stripper) from a stripper supply device 1100 (e.g., nozzle, sprayer, applicator, stripper source or supply) can be applied to the undeveloped portion 710b of the mask layer 710 to remove (e.g., clean) the undeveloped portion 710b of the mask layer 710 from the hydrophobic exposed surface 133 of the insulative layer 132 in accordance with embodiments of the disclosure.

FIG. 12 shows an exemplary embodiment of the patterned insulative layer 132 including the exposed hydrophobic surface 133 manufactured by the exemplary methods of FIGS. 6-11 after the method of removing the undeveloped portion 710b of the mask layer 710 of FIG. 11 in accordance with embodiments of the disclosure. In some embodiments, based at least on the features and methods of the disclosure, the hydrophobic exposed surface 133 of the insulative layer 132 can be provided as a free-surface including predetermined parameters (e.g., at least hydrophobic material properties) defined to permit function and operation of the liquid lens 100 in accordance with embodiments of the disclosure. Additionally, in some embodiments, the patterned insulative layer 132 can include a perimeter or boundary 134 (e.g., edge, outer edge) formed as a result of patterning the insulative layer 132. In some embodiments, the perimeter or boundary 134 of the patterned insulative layer 132 can define a location corresponding to the uncovered portion of the common electrode 124 that is not covered by or exposed adjacent to the insulative layer 132.

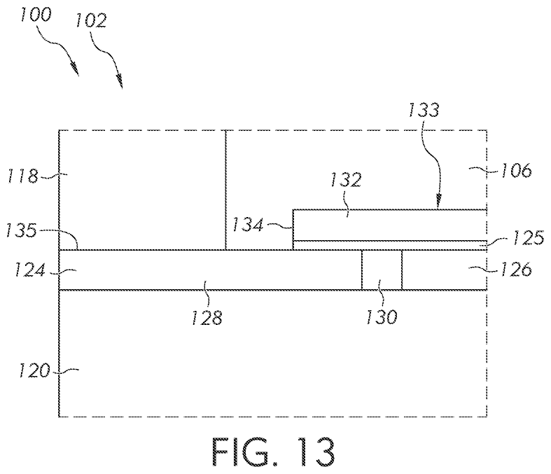

Accordingly, in some embodiments, the patterned insulative layer 132 manufactured with one or more features of the photolithography process of the disclosure can be employed (e.g., incorporated) in a liquid lens 100. For example, FIG. 13 shows an exemplary embodiment of a portion of the liquid lens 100 including the patterned insulative layer 132 of FIG. 12 in accordance with embodiments of the disclosure. For example, in some embodiments, after performing the photolithography process to provide the patterned insulative layer 132, the first fluid 106 and the second fluid 108 can be added to the cavity 104, and the cavity 104 can be hermetically sealed. In some embodiments, the first outer layer 118 can be bonded to the intermediate layer 120 by bond 135 and the second outer layer 122 can be bonded to the intermediate layer 120 by bond 136. For example, in some embodiments, one or more of the bonds 135, 136 can be formed by a bonding technique (e.g., laser bonding, laser beam welding) or other bonding processes in accordance with embodiments of the disclosure. Thus, in some embodiments, features and methods of the disclosure, can provide the lens body 102 as a hermetically sealed package, where contents (e.g., first fluid 106, second fluid 108, patterned insulative layer 132) contained within the cavity 104 are hermetically sealed within the cavity 104 of the lens body 102.

Moreover, in some embodiments, methods of patterning in accordance with embodiments of the disclosure can provide a liquid lens 100 including a hermetically sealed lens body 102 with the patterned insulative layer 132 including the hydrophobic exposed surface 133 in contact with at least one of the first fluid 106 and the second fluid 108 capable of being employed and operated in a variety of applications for long durations of time (e.g., on the order of 5, 10, 15, 20 or more years) without degradation of the patterned insulative layer 132 including the hydrophobic exposed surface 133. Thus, in some embodiments, the liquid lens 100 including the patterned insulative layer 132 and the hydrophobic exposed surface 133 can be provided within the sealed cavity 104 of the lens body 102 with continuous hermeticity for the long durations of time while being employed and operated in a variety of applications.

Accordingly, in some embodiments, by patterning the insulative layer 132 in accordance with embodiments of the disclosure, the hydrophobic exposed surface 133 of the insulative layer 132 can provide the liquid lens 100 with features advantageous for operation (e.g., modification of a shape) of the liquid lens defined as the interface 110 between the first liquid 106 and the second liquid 108. For example, in some embodiments, the patterned insulative layer 132 manufactured by the exemplary methods of FIGS. 5-11 including the patterning process of FIGS. 7-11, and schematically illustrated in the exemplary embodiment of the portion of the liquid lens 100 of FIG. 13 can correspond to the portion of the liquid lens 100 taken at view 4 of FIG. 1 and, therefore, be employed in the liquid lens 100 of FIGS. 1-3 as disclosed in accordance with embodiments of the disclosure.

In some embodiments, the profile of the bore 105 of the intermediate layer 120 including the orientation or inclination of the sidewalls including the exposed surface 133 of the insulative layer 132 as well as the surface energies of the first liquid 106, the second liquid 108, and the insulative layer 132 can define the shape (e.g., curvature) of the interface 110. Additionally, in some embodiments, the shape of the interface 110 can be modulated by application of voltage to the common electrode 124 and the driving electrode 126 of the conductive layer 128 based on the principle of electrowetting as set forth above.

Some electrowetting lenses (e.g., described in literature) can be macro-optic devices fabricated by piece assembly. However, fabricating an array of micro-optic lenses by a semiconductor or MEMS type fabrication process can present additional challenges with respect to patterning of the dielectric (e.g., insulative layer 132). Moreover, it can be appreciated that a challenge to manufacturing an electrowetting device such as the liquid lens 100 of the present disclosure can include providing a stable dielectric to prevent conduction of charge from the driving electrode 126 to the conductive polar fluid (e.g., first liquid 106). Additionally, in some embodiments, the insulative layer 132 should have high dielectric breakdown strength as the drive voltage of electrowetting lenses can operate, for example, from about 50V to about 100V. As noted, the exposed surface 133 of the insulative layer 132 should include hydrophobic material properties to enable the change in the high contact angle with respect to the polar fluid (e.g., first liquid 106) as the shape of the interface 110 between the first liquid 106 and the lower index non-polar fluid (e.g., second liquid 108) is modulated based on electrowetting. Moreover, the exposed surface 133 of the surface of the insulative layer 132 should be smooth so that surface perturbations do not cause contact angle hysteresis while the lens power is cycled. Likewise, in some embodiments, the insulative layer 132 should be stable against interactions with the polar and non-polar fluids (e.g., first liquid 106, second liquid 108) which could otherwise cause changes in contact angle, dielectric constant, dielectric breakdown, or surface roughness over duration of employment of the liquid lens 100.

In some embodiments, an advantage of a photolithographic patterning method as compared to mechanical masking can include achieving a cleaner, more defined dielectric layer edge (e.g., perimeter or boundary 134 of insulative layer 132) with respect to a finished lens. For example, in some embodiments, one or more methods not including features of the disclosure (e.g., tape masking) may produce defects (e.g., Parylene flaps, Parylene stringers) in the insulative layer 132. However, in some embodiments, such defects were not present after photolithography followed by dry etch in accordance with embodiments of the disclosure. Therefore, in addition to enabling mass production, in some embodiments, methods of the disclosure can greatly improve yield. For example, in some embodiments, photolithographically patterned dielectric can improve long-term durability of the insulative layer 132 by preventing dielectric delamination which can occur at the pattern edge (e.g., perimeter or boundary 134 of insulative layer 132) with conventional patterning methods.

Lithographic processes described in the literature typically employ a hard metal mask such as aluminum, a CVD, or spin-on dielectric mask such as SiO₂ or SiNx. However, without intending to be bound by theory, in some embodiments, the interaction of hard mask deposition with the surface of the dielectric can irreversibly increase the surface energy, thereby altering the hydrophobicity of the dielectric provided for operation of the liquid lens based on electrowetting. Additionally, in some embodiments, dielectrics (e.g., parylene) can be dry etched at least in part because their chemical inertness can make liquid patterning challenging. Dry etch processes using oxygen or other oxidizers optionally with argon for increased sputtering are well described in the literature. For example, in some embodiments, even brief exposure of Parylene surfaces to nitrogen plasma or oxygen plasma can functionalize the Parylene surface increasing polar surface energy, thereby altering the hydrophobicity of the dielectric. However, a common feature of some lithographic processes focuses on patterning the dielectric and is not concerned with maintaining a hydrophobic surface.

Thus, as set forth in the present disclosure, patterning of a dielectric by dry etch can employ effective masking to protect the dielectric surface from the plasma and maintain the desired hydrophobicity of the dielectric surface. For example, in some embodiments, features and methods of the disclosure can provide an electrowetting optical device structure (e.g., liquid lens 100) with an array of more than one lens in which a hydrophobic dielectric (e.g., insulative layer 132 including hydrophobic exposed surface 133) can be patterned by lithographic means (e.g., photolithography) to remove the dielectric from one or more regions (e.g., one or more regions of conductive layer 128) such that the polymer dielectric surface (e.g., exposed surface 133 of insulative layer 132) maintains a surface energy below 40 mJ/m². Accordingly, in some embodiments, features and methods of the disclosure can pattern the insulative layer while maintaining the hydrophobicity of the dielectric suitable for operating a liquid lens employing electrowetting in accordance with embodiments of the disclosure.

As disclosed with respect to FIGS. 7-11, in some embodiments, a method of patterning the insulative layer 132 can include deposition of a hard mask (e.g., mask material 701 to provide mask layer 710, FIG. 7), lithographic patterning (e.g., pattern 805 and electromagnetic source 800, FIG. 8), etching of the hard mask (e.g., etching exposed portion 710a of mask layer 710 with etchant 901, FIG. 9), dry etching of the dielectric (e.g., etching insulative layer 132 with etchant 1001, FIG. 10), and removal of the mask material (e.g., removing unexposed portion 710b of mask layer 710 with stripper 1101, FIG. 11) to provide the patterned dielectric (e.g., patterned insulative layer 132, FIG. 12).

Pattern transfer to maintain a hydrophobic surface (e.g., exposed surface 133) suggests that both the mask deposition process (e.g., mask layer 710, FIG. 7) as well as the mask etching (e.g., FIGS. 8-11) should not greatly alter the dielectric surface energy. In some embodiments, hard masks (e.g., mask layer 710, FIG. 7) can include metals, oxides, carbides, nitrides. Typical deposition methods (e.g., mask material 701 from mask material source 700) can include, but are not limited, to thermal and e-beam evaporation, CVD, PECVD, spin-on and spray on sol-gel or colloidal solutions.

As set forth in TABLE 1, a large number of potential hard mask materials (e.g., mask layer 710) were considered along with their etch chemistry. TABLE 1 shows Parylene surface energy (e.g., surface energy of exposed surface 133 of insulative layer 132) before and after exposure to etchants (e.g., developer material 901 from a developer material supply device 900), rinsing, and drying as measured by static contact angle with DI water, hexadecane, and diiodomethane and fit using the Wu model. Etchant and etch process listed were chosen as appropriate for 1000 A thick sputtered, e-beam and thermally evaporated hard mask materials listed. Advantageously, none of the etchants considered showed significant impact on Parylene surface energy.

TABLE 1

| Potential Mask | Etchant | W | HD | DIM | D | P | T |
|---|---|---|---|---|---|---|---|
| | control, do nothing | 94.56 | 7.26 | 44.26 | 32.11 | 4.06 | 36.17 |
| Zn, ZnO, Mn | 1% HCl 40 C. 60 sec | 96.86 | 7.2 | 39.5 | 33.06 | 3.05 | 36.11 |
| SnO2 | Transcene TE-100 40 C. 60 sec | 93.6 | 7.8 | 46.63 | 31.62 | 4.53 | 36.15 |
| Cr, Cu | Chrome etchant Transcene | 92.2 | 7.06 | 42.43 | 32.5 | 4.89 | 37.38 |
| | 1020 40 C. 60 sec | | | | | | |
| Al, Mo | Type A Al etchant 40 C. 60 sec | 96.66 | 7.26 | 39.9 | 32.98 | 3.14 | 36.11 |
| Cu | Copper APS-100 40 C. 60 sec | 92.86 | 7.8 | 40 | 32.94 | 4.54 | 37.47 |
| Ni | Nickel APS 40 C. 60 s | 94.56 | 6.86 | 42.43 | 32.51 | 3.99 | 36.49 |
| | control, do nothing | 94.86 | 7.4 | 41.13 | 32.74 | 3.83 | 36.57 |

Additionally, the impact of sputtering, and both thermal and e-beam evaporation of metal hard masks on Parylene surface energy was examined by sputtering ZnO films from an oxide target in a confocal sputter tool at room temperature. TABLE 2 shows Parylene surface energy before and after exposure to HCl etchant, and sputtered ZnO hard mask and etching as measured by static contact angle with DI water, hexadecane, and diiodomethane and fit using the Wu model.

TABLE 2

| | W | HD | DIM | D | P | T |
|---|---|---|---|---|---|---|
| Parylene Control | 98 | 7.93 | 41.66 | 32.6 | 2.75 | 35.35 |
| Parylene Etched 1% HCl 23 | 93.93 | 7 | 37.36 | 33.46 | 4.07 | 37.52 |
| C. 2 min | | | | | | |
| Parylene after 10 nm ZnO | 55.53 | 17.56 | 26.6 | 34.52 | 21.55 | 56.07 |
| sputtered at 100 W, and | | | | | | |
| etched | | | | | | |
| Parylene after 39 nm ZnO | 48.66 | 18.13 | 23.86 | 34.82 | 25.07 | 59.89 |
| sputtered at 200 W, and | | | | | | |
| etched | | | | | | |

Parylene upon which a ZnO had been deposited exhibited a surface energy greater than 55 mJ/m². Exposure to the etchant alone did not alter the contact angle, consistent with the surface energy increase resulting from the deposition process itself. One would expect thermal or e-beam evaporation to be less energetic and cause lower surface damage. Copper hard masks were thermally evaporated on Parylene-C and surface energy measured after removal as shown in TABLE 3.

TABLE 3

| Sample | W | HD | DIM | D | P | T |
|---|---|---|---|---|---|---|
| Parylene-C | 98.13 | 7.73 | 36.43 | 33.61 | 3.76 | 37.37 |
| Parylene-C, APS-100 | 87.53 | 8.36 | 33.56 | 34.08 | 7.78 | 41.85 |
| Parylene-C, evap 50 | 72.03 | 8 | 42 | 32.54 | 15.11 | 47.65 |
| nm Cu, APS-100 | | | | | | |

The surface energy of Parylene-C was raised to 47 mJ/m² on samples upon which the metal mask was deposited, consistent with the interaction of metal deposits with the Parylene-C surface creating some polar functionalities which increase surface energy. From these results it can be observed, with respect to mask layer 710, that metal and oxide hard masks may not be suitable and organic masks can, therefore, be employed to enable pattern transfer.

Photoresist is commonly employed as a hard mask for photolithographic pattern transfer. It should be noted that HMDS, the typical adhesion promoter employed for application of photoresist on Si or glass, can irreversibly raise the surface energy of the dielectric film. For example, TABLE 4 shows the surface energy of Parylene-C, and Parylene-C after spin-coating with AZ4210 photoresist, soft baking and stripping in acetone and IPA, and Parylene-C vapor primed with HMDS, AZ4210 coated, soft baked, and stripped. HMDS treatment increased the surface energy to 43 mJ/m² and decreased water contact angle to 81 degrees. Without wishing to be bound by theory, this is believed to be a result of the trimethylsilyl tail groups orienting toward the highly non-polar surface of the Parylene-C, leaving the reactive silazane groups free to interact with each other and the environment.

TABLE 4

| Sample | W | HD | DIM | D | P | T |
|---|---|---|---|---|---|---|
| Parylene-C | 88.43 | 8.3 | 36.56 | 33.55 | 7.5 | 41.04 |
| Parylene-C, AZ4210 coated | 86.66 | 7.73 | 36.83 | 33.54 | 8.2 | 41.74 |
| and stripped with acetone | | | | | | |
| and IPA | | | | | | |
| Parylene-C, HMDS treated, | 81.86 | 10.33 | 28.43 | 32.98 | 10.38 | 43.35 |
| AZ4210 coated and stripped | | | | | | |
| with acetone and IPA | | | | | | |

The challenge of using a photoresist mask for pattern transfer is no selectivity in etch between photoresist and dielectric (e.g., Parylene). For example, in some embodiments, both etch in oxidizing environments, typically Nitrogen and O2 plasma with or without some Argon addition. Selectivity is near unity, so patterning a 2 um Parylene film can require at least 2 um of photoresist at all places. Thus, in some embodiments, dielectric patterning of the electrowetting lens array described should include uniform photoresist coating over the topography of the bore 105 of the intermediate layer 120. Typical spin processes for applying photoresist may not yield a uniform resist coating on the structure of the bore 105 based at least on the three-dimensional profile of the bore 105. For example, in some embodiments, streamers were observed from each bore 105, and the resist was thin at the top corner (e.g., wider end 105b) of each bore 105 as surface tension reduced thickness at the top corner and increased thickness at the bottom corner (e.g., narrow end 105a) of each bore 105. Accordingly, in some embodiments, spray application of photoresist has been demonstrated to provide more uniform coverage in complex topography.

TABLE 5A and TABLE 5B show photoresist coverage as measured by SEM on set of samples sprayed on a Suss Gamma track system with Shipley 1805 photoresist as a function of hot plate temperature, photoresist flow rate, and photoresist and drying control agent concentrations on plate samples. N2 flow rate on the atomizer was constant at 20 slm. Achieving acceptable surface coverage of the mask layer 710 on the insulative layer 132 employed high hotplate temperature, no drying control agent (PGMEA), and high photoresist concentration. This is consistent with a model suggesting that the resist droplet quickly hit gel point before the droplet wets the surface and surface tension thins the liquid film over the top corner (e.g., wider end 105b) of the cone (e.g., bore 105) to minimize surface energy. For example, in some embodiments, inadequate coverage over the top corner of the cone can lead to erosion of the mask and etching of the Parylene at the top corner. This can lead to either or both a localized increase in Parylene surface energy impacting lens performance, or delamination of the Parylene film.

TABLE 5A

| | Hot Plate | PR Flow Rate | PR Conc. | DCA Conc. | Top PR | Side PR | Bott PR | Ave Pr |
|---|---|---|---|---|---|---|---|---|
| Run | (C.) | (ml/min) | (Vol %) | (Vol %) | (um) | (um) | (um) | (um) |
| 1 | 85 | 1 | 0.05 | 0 | 3 | 2.2 | 1.6 | 2.3 |
| 2 | 85 | 1 | 0.2 | 0.2 | 2.5 | 3.9 | 2.3 | 2.9 |
| 3 | 85 | 1 | 0.05 | 0 | 4.8 | 6.4 | 4 | 5.1 |
| 4 | 85 | 2.5 | 0.2 | 0.2 | 1.5 | 5 | 2.4 | 3 |
| 5 | 65 | 2.5 | 0.05 | 0 | 1.7 | 2.6 | 1 | 1.8 |
| 6 | 65 | 1 | 0.05 | 0.2 | 2.2 | 3.3 | 2.1 | 2.5 |
| 7 | 85 | 2.5 | 0.2 | 0 | 4 | 6.1 | 4.5 | 4.9 |
| 8 | 65 | 1 | 0.2 | 0 | 2.4 | 6 | 3 | 3.8 |
| 9 | 65 | 2.5 | 0.2 | 0 | 2.6 | 8.2 | 4.4 | 5.1 |
| 10 | 65 | 1 | 0.2 | 0.2 | 1.8 | 4.6 | 4.6 | 3.7 |
| 11 | 85 | 2.5 | 0.05 | 0.2 | 1.6 | 3.7 | 2.1 | 2.5 |
| 12 | 65 | 2.5 | 0.05 | 0.2 | 2.2 | 3.5 | 1.9 | 2.5 |

TABLE 5B

| | Ave | min | Top | Bottom | AFM Rq | | |
|---|---|---|---|---|---|---|---|
| Run | Coverage | Coverage | Coverage | Coverage | (nm) | Bubbles | Delam |
| 1 | 1.05 | 0.73 | 1.36 | 0.73 | 80 | 1 | 0 |
| 2 | 0.62 | 0.59 | 0.64 | 0.59 | 15.2 | 0 | 1 |
| 3 | 0.69 | 0.63 | 0.75 | 0.63 | 15 | 0 | 1 |
| 4 | 0.39 | 0.3 | 0.3 | 0.48 | 84.3 | 0.5 | 0.5 |
| 5 | 0.52 | 0.38 | 0.65 | 0.38 | 11.3 | 1 | 0 |
| 6 | 0.65 | 0.64 | 0.67 | 0.64 | 7.9 | 0.5 | 1 |
| 7 | 0.7 | 0.66 | 0.66 | 0.74 | 10.3 | 0 | 1 |
| 8 | 0.45 | 0.4 | 0.4 | 0.5 | 8 | 0 | 1 |
| 9 | 0.43 | 0.32 | 0.32 | 0.54 | 6.8 | 0 | 1 |
| 10 | 0.7 | 0.39 | 0.39 | 1 | 33.3 | 0.5 | 0.5 |
| 11 | 0.5 | 0.43 | 0.43 | 0.57 | 2.7 | 1 | 0 |
| 12 | 0.59 | 0.54 | 0.63 | 0.54 | 71 | 1 | 1 |

As disclosed with respect to FIG. 10, based on experimentation, the Parylene was etched in an inductively coupled plasma dry etcher (e.g., etching source 1000 providing etchant 1001) with He-backside cooling to avoid heating the Parylene. Parylene etch rates of ˜1 um/min were achieved with 900 W power, 100 W bias, 40 sccm O2 flow, and 3.5 mTorr. As disclosed with respect to FIG. 11, in some embodiments, low pressure enabled the photoresist (e.g., undeveloped portion 710b of mask layer 710) to be stripped cleanly afterward and avoided un-strippable Parylene by-products. The photoresist was stripped using Acetone soak, followed by IPA and DI rinse (e.g., stripper source 1100 providing stripper 1101).

Moreover, in some embodiments, a dielectric including Parylene-C (e.g., insulative layer 132) can have great chemical stability toward solvents (e.g., stripper material 1101, FIG. 11) and, therefore, should permit lithographic processing for patterning using semiconductor and MEMs fabrication. In some embodiments, Parylene-C can be swelled in aromatic and chlorinated solvents, such as benzene, chloroform, trichloroethylene, and toluene while more polar solvents such as methanol, 2-propanol, ethylene glycol, and water may not cause any swelling. For example, as shown in TABLE 6, tests of soaking Parylene-C films (e.g., insulative layer 132) in solvents (e.g., stripper material 1101) typically employed as resist strippers (e.g., Acetone, NMP, and Orthogonal Stripper) showed minimal interaction with respect to altering the surface energy of the as received sample film (e.g., surface energy of exposed surface 133 of insulative layer 132) defined as 37.62 mJ/m².

TABLE 6

| Sample | SE (mJ/m2) |
|---|---|
| As Received | 37.62 |
| Acetone | 42.33 |
| NMP | 39.12 |
| Orthogonal Stripper | 33.61 |

Accordingly, as disclosed with respect to FIG. 12, in some embodiments, the finished lenses patterned by photolithography in accordance with embodiments of the disclosure included identical electro-optical properties with respect to mechanically masked devices, thereby confirming that the employed patterning process can maintain the sensitive hydrophobic surface of the dielectric. Accordingly, in some embodiments, features and methods of the disclosure can enable patterning of the insulative layer while maintaining the hydrophobicity of the dielectric (e.g., surface energy below 40 mJ/m²) suitable for operating a liquid lens employing electrowetting in accordance with embodiments of the disclosure.

In some embodiments, a method of manufacturing a liquid lens (e.g., liquid lens 100) can include applying a mask layer (e.g., mask layer 710) to an insulative layer (e.g., insulative layer 132). In some embodiments, a conductive layer (e.g., conductive layer 128) can be disposed between a substrate (e.g., intermediate layer 120) and the insulative layer within a bore (e.g., bore 105) of the substrate. In some embodiments, the method can include selectively exposing a first portion (e.g., portion 710a) of the mask layer to electromagnetic radiation (e.g., electromagnetic radiation 801a) without exposing a second portion (e.g., portion 710b) of the mask layer to the electromagnetic radiation. In some embodiments, the method can include developing the first portion of the mask layer to expose a first portion of the insulative layer. In some embodiments, the method can include selectively etching the first portion of the insulative layer to expose a portion of the conductive layer comprising a first pattern corresponding to the first portion of the mask layer. In some embodiments, the method can include removing the second portion of the mask layer to expose a second portion of the insulative layer comprising a second pattern corresponding to the second portion of the mask layer and a surface energy below 40 mJ/m².

In some embodiments, the second portion of the insulative layer can have a hydrophobic surface (e.g., hydrophobic surface 133). In some embodiments, the mask layer can include a photoresist. In some embodiments, the insulative layer can include Parylene. In some embodiments, the applying the mask layer can include spraying a photoresist material onto the insulative layer. In some embodiments, the selectively etching the first portion of the insulative layer to expose a portion of the conductive layer can include plasma etching.

In some embodiments, the method can include adding a polar liquid (e.g., first liquid 106) and a non-polar liquid (e.g., second liquid 108) to a cavity that can be defined at least in part by the bore of the substrate. In some embodiments, the polar liquid and the non-polar liquid can be substantially immiscible such that an interface (e.g., interface 110) defined between the polar liquid and the non-polar liquid forms a lens. In some embodiments, the method can include bonding a second substrate (e.g., first outer layer 118) to the substrate to hermetically seal the polar liquid, the non-polar liquid, and the second portion of the insulative layer within the cavity. In some embodiments, the method can include subjecting the polar liquid and the non-polar liquid to an electric field and changing a shape of the interface by adjusting the electric field to which the polar liquid and the non-polar liquid are subjected. In some embodiments, a liquid lens manufactured by the method can include the substrate, the conductive layer, and the second portion of the insulative layer.

As noted, although a single liquid lens is described and illustrated in the drawing figures, unless otherwise noted, it is to be understood that, in some embodiments, a plurality of liquid lenses can be provided, and one or more of the plurality of liquid lenses can include the same or similar features as the single liquid lens, without departing from the scope of the disclosure.

For example, in some embodiments, the plurality of liquid lenses can be manufactured more efficiently (e.g., simultaneously, faster, less expensively, in parallel) as an array (e.g., based on micro-electro-mechanical system (MEMs) wafer scale fabrication) including the plurality of liquid lenses. For example, as compared to manufacturing a plurality of single liquid lenses manually (e.g., by human hand) or individually and separately, in some embodiments, an array including the plurality of liquid lenses can be manufactured automatically by a micro-electro-mechanical system including a controller (e.g., computer, robot), thereby increasing one or more of the manufacturing efficiency, the rate of production, the scalability, and the repeatability of the manufacturing process.

Moreover, in some embodiments, for example, after manufacturing the array including the plurality of liquid lenses, one or more liquid lenses can be separated from the array (e.g., singulation) and provided as a single liquid lens in accordance with embodiments of the disclosure. In some embodiments, whether manufactured as a single liquid lens or an array including a plurality of liquid lenses, the liquid lens of the present disclosure can be provided, manufactured, operated, and employed in accordance with embodiments of the disclosure without departing from the scope of the disclosure.

Accordingly, in some embodiments, a method of manufacturing an array including a plurality of liquid lenses can include applying a mask layer to an insulative layer. In some embodiments, a conductive layer can be disposed between a substrate and the insulation layer within each bore of a plurality of bores of the substrate. In some embodiments, the method can include selectively exposing a plurality of first portions of the mask layer to electromagnetic radiation without exposing a plurality of second portions of the mask layer to the electromagnetic radiation. In some embodiments, the method can include developing the plurality of first portions of the mask layer to expose a plurality of first portions of the insulative layer. In some embodiments, the method can include selectively etching the plurality of first portions of the insulative layer to expose a plurality of portions of the conductive layer comprising a first pattern corresponding to the plurality of first portions of the mask layer. In some embodiments, the method can include removing the plurality of second portions of the mask layer to expose a plurality of second portions of the insulative layer including a second pattern corresponding to the plurality of second portions of the mask layer and a surface energy below 40 mJ/m²

In some embodiments, the plurality of second portions of the insulative layer can including a hydrophobic surface. In some embodiments, the mask layer can include a photoresist. In some embodiments, the insulative layer can include Parylene. In some embodiments, the applying the mask layer can include spraying a photoresist material onto the insulative layer. In some embodiments, the selective etching the plurality of first portions of the insulative layer to expose a plurality of portions of the conductive layer can include plasma etching.

In some embodiments, the method can include adding a polar liquid and a non-polar liquid to each cavity of the plurality of cavities. Each cavity of the plurality of cavities can be defined at least in part by a corresponding bore of a plurality of bores of the substrate. In some embodiments, the polar liquid and the non-polar liquid can be substantially immiscible such that an interface defined between the polar liquid and the non-polar liquid in each cavity of the plurality of cavities can define a corresponding lens of the plurality of lenses. In some embodiments, the method can include bonding a second substrate to the first substrate to hermetically seal the polar liquid and the non-polar liquid of each corresponding cavity of the plurality of cavities and a corresponding second portion of the second portions of the insulative layer within the corresponding cavity of the plurality of cavities.

In some embodiments, the method can include separating each liquid lens of the plurality of liquid lenses from the array. In some embodiments, the method can include subjecting the polar liquid and the non-polar liquid of at least one lens of the plurality of lenses to an electric field and changing a shape of the interface by adjusting the electric field to which the polar liquid and the non-polar liquid are subjected.

In some embodiments, a liquid lens comprises a cavity defined at least in part by a bore of a substrate. The liquid lens can include a conductive layer disposed within the bore and an insulative layer disposed within the bore such that the conductive layer is disposed between the substrate and the insulative layer. The liquid lens can further include a polar liquid and a non-polar liquid disposed within the cavity. The polar liquid and the non-polar liquid can be substantially immiscible such that an interface defined between the polar liquid and the non-polar liquid forms a lens. The interface can intersect a surface of the insulative layer including a surface energy below 40 mJ/m².

In some embodiments, the surface of the insulative layer can comprise a hydrophobic surface. In some embodiments, the insulative layer can comprise Parylene. In some embodiments, the liquid lens can further comprise a second substrate bonded to the substrate, wherein the polar liquid, the non-polar liquid, and the insulative layer are hermetically sealed within the cavity.

In some embodiments, an array can comprise a plurality of liquid lenses. In some embodiments, the array can comprise a substrate comprising a plurality of bores. In some embodiments, the array can further comprise a plurality of cavities. In some embodiments, each cavity of the plurality of cavities can be defined at least partially by a corresponding bore of the plurality of bores. In some embodiments, the array can further comprise a conductive layer disposed within each bore of the plurality of bores. In some embodiments, the array can still further comprise an insulative layer disposed within each bore of the plurality of bores. In some embodiments, the conductive layer can be disposed between the substrate and the insulative layer within each bore of the plurality of bores. In some embodiments, the array can include a polar liquid and a non-polar liquid disposed within each cavity of the plurality of cavities. In some embodiments, the polar liquid and the non-polar liquid can be substantially immiscible such that an interface defined between the polar liquid and the non-polar liquid in each cavity of the plurality of cavities defines a corresponding lens of the plurality of liquid lenses. In some embodiments, the interface of each cavity of the plurality of cavities can intersect a corresponding surface portion of the insulative layer located within each corresponding bore of the plurality of bores. In some embodiments, each surface portion of the insulative layer can include a surface energy below 40 mJ/m².

In some embodiments, each surface portion of the insulative layer can comprise a hydrophobic surface. In some embodiments, the insulative layer can comprise Parylene. In some embodiments, the array can further comprise a second substrate bonded to the substrate. The polar liquid and the non-polar liquid of each corresponding cavity of the plurality of cavities and each surface portion of the insulative layer of each corresponding bore of the plurality of bores can be hermetically sealed within the corresponding cavity of the plurality of cavities.

Embodiments and the functional operations described herein can be implemented in digital electronic circuitry, or in computer software, firmware, or hardware, including the structures disclosed in this specification and their structural equivalents, or in combinations of one or more of them. Embodiments described herein can be implemented as one or more computer program products, i.e., one or more modules of computer program instructions encoded on a tangible program carrier for execution by, or to control the operation of, data processing apparatus. The tangible program carrier can be a computer readable medium. The computer readable medium can be a machine-readable storage device, a machine-readable storage substrate, a memory device, or a combination of one or more of them.

The term “processor” or “controller” can encompass all apparatus, devices, and machines for processing data, including by way of example a programmable processor, a computer, or multiple processors or computers. The processor can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, or declarative or procedural languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes described herein can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit) to name a few.

Processors suitable for the execution of a computer program include, by way of example, both general and special purpose microprocessors, and any one or more processors of any kind of digital computer. Generally, a processor will receive instructions and data from a read only memory or a random-access memory or both. The essential elements of a computer are a processor for performing instructions and one or more data memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), to name just a few.

Computer readable media suitable for storing computer program instructions and data include all forms data memory including nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, embodiments described herein can be implemented on a computer having a display device, e.g., a CRT (cathode ray tube) or LCD (liquid crystal display) monitor, and the like for displaying information to the user and a keyboard and a pointing device, e.g., a mouse or a trackball, or a touch screen by which the user can provide input to the computer. Other kinds of devices can be used to provide for interaction with a user as well; for example, input from the user can be received in any form, including acoustic, speech, or tactile input.

Embodiments described herein can be implemented in a computing system that includes a back end component, e.g., as a data server, or that includes a middleware component, e.g., an application server, or that includes a front end component, e.g., a client computer having a graphical user interface or a Web browser through which a user can interact with implementations of the subject matter described herein, or any combination of one or more such back end, middleware, or front end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Likewise, a “plurality” is intended to denote “more than one.”

Ranges can be expressed herein as from “about” one particular value, and/or to “about” another particular value. When such a range is expressed, embodiments include from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to an apparatus that comprises A+B+C include embodiments where an apparatus consists of A+B+C and embodiments where an apparatus consists essentially of A+B+C.

It will be apparent to those skilled in the art that various modifications and variations can be made to the present disclosure without departing from the spirit and scope of the appended claims. Thus, it is intended that the present disclosure cover the modifications and variations of the embodiments herein provided they come within the scope of the appended claims and their equivalents.

It should be understood that while various embodiments have been described in detail with respect to certain illustrative and specific embodiments thereof, the present disclosure should not be considered limited to such, as numerous modifications and combinations of the disclosed features are possible without departing from the scope of the following claims.

1. A method of patterning an insulative layer, the method comprising:
applying a mask layer to the insulative layer;
selectively exposing a first portion of the mask layer to electromagnetic radiation without exposing a second portion of the mask layer to the electromagnetic radiation;
developing the first portion of the mask layer to expose a first portion of the insulative layer;
selectively etching the first portion of the insulative layer to expose a portion of a conductive layer comprising a first pattern corresponding to the first portion of the mask layer; and
removing the second portion of the mask layer to expose a second portion of the insulative layer comprising a second pattern corresponding to the second portion of the mask layer and a surface energy below 40 mJ/m².

2. The method of claim 1, wherein the second portion of the insulative layer comprises a hydrophobic surface.

3. The method of claim 1, wherein the mask layer comprises a photoresist.

4. The method of claim 1, wherein the insulative layer comprises Parylene.

5. The method of claim 1, wherein the applying the mask layer comprises spraying a photoresist material onto the insulative layer.

6. The method of claim 1, wherein the selectively etching the first portion of the insulative layer to expose a portion of the conductive layer comprises plasma etching.

7. The method of claim 1, wherein the conductive layer is disposed between a substrate and the insulative layer within a bore of the substrate, the method comprising adding a first liquid and a second liquid to a cavity defined at least in part by the bore of the substrate, wherein the first liquid and the second liquid are substantially immiscible such that an interface defined between the first liquid and the second liquid forms a lens.

8. The method of claim 7, comprising bonding a second substrate to the substrate to hermetically seal the first liquid, the second liquid, and the second portion of the insulative layer within the cavity.

9. The method of claim 7, comprising subjecting the first liquid and the second liquid to an electric field and changing a shape of the interface by adjusting the electric field to which the first liquid and the second liquid are subjected.

10. A liquid lens manufactured by the method of claim 1, comprising a substrate, the conductive layer, and the second portion of the insulative layer.

11. A method of manufacturing an array comprising a plurality of liquid lenses, the method comprising:
applying a mask layer to an insulative layer, wherein a conductive layer is disposed between a substrate and the insulative layer within a plurality of bores of the substrate;
selectively exposing a plurality of first portions of the mask layer to electromagnetic radiation without exposing a plurality of second portions of the mask layer to the electromagnetic radiation;
developing the plurality of first portions of the mask layer to expose a plurality of first portions of the insulative layer;
selectively etching the plurality of first portions of the insulative layer to expose a plurality of first portions of the conductive layer comprising a first pattern corresponding to the plurality of first portions of the mask layer; and
removing the plurality of second portions of the mask layer to expose a plurality of second portions of the insulative layer comprising a second pattern corresponding to the plurality of second portions of the mask layer and a surface energy below 40 mJ/m².

12. The method of claim 11, wherein the plurality of second portions of the insulative layer comprises a hydrophobic surface.

13. The method of claim 11, wherein the mask layer comprises a photoresist.

14. The method of claim 11, wherein the insulative layer comprises Parylene.

15. The method of claim 11, wherein the applying the mask layer comprises spraying a photoresist material onto the insulative layer.

16. The method of claim 11, wherein the selective etching the plurality of first portions of the insulative layer to expose the plurality of first portions of the conductive layer comprises plasma etching.

17. The method of claim 11, comprising:
adding a first liquid and a second liquid to each cavity of a plurality of cavities;
wherein each cavity of the plurality of cavities is defined at least in part by a corresponding bore of the plurality of bores of the substrate; and
wherein the first liquid and the second liquid are substantially immiscible such that an interface defined between the first liquid and the second liquid in each cavity of the plurality of cavities defines a corresponding lens of the plurality of liquid lenses.

18. The method of claim 17, comprising bonding a second substrate to the first substrate to hermetically seal the first liquid and second liquid of each corresponding cavity of the plurality of cavities and a corresponding second portion of the plurality of second portions of the insulative layer within the corresponding cavity of the plurality of cavities.

19. The method of claim 18, comprising separating each liquid lens of the plurality of liquid lenses from the array.

20. The method of claim 17, comprising subjecting the first liquid and the second liquid of at least one liquid lens of the plurality of liquid lenses to an electric field and changing a shape of the corresponding interface by adjusting the electric field to which the first liquid and the second liquid are subjected.

21-30. (canceled)
